(19) United States
(12) Patent Application Publication
(10) Pub. No.: US 2003/0112860 A1
(43) Pub. Date: Jun. 19, 2003

(54) Method and system for shortening channel impulse response using time domain equalization filter

(76) Inventor: Alper Tunga Erdogan, Kucukesat (TR)

Correspondence Address: Kevin T. Duncan, Esq., Hunton & Williams, Intellectual Property Department, 1900 K Street, N.W., Suite 1200, Washington, DC, 20006, US

(21) Appl. No.: 10/020,214

(22) Filed: Dec. 18, 2001

(51) Int. Cl. H03H 7/30

(52) U.S. Cl. 375/229

(57) ABSTRACT

A TEQ filter is provided for applications with asymmetric transmit and receive rates, such as for use in, for example, ADSL and VDSL applications. In particular, the present invention provides for a physical layer solution in which a channel impulse response is shortened by modeling a desired target impulse response based on a hypothetical delay channel. The target channel length is approximately matched to yield a set of TEQ filter coefficients or family of parameters. The TEQ filter coefficients or parameters when applied to the given channel impulse response yields a shortened channel impulse response to improve efficiency of data flow. Channel effects, receiver effects and other noise or disturbance effects are considered in modeling the system to derive the TEQ filter coefficients to generate the desired shortened channel impulse response. A minimum mean square error linearly constrained fast algorithm may be used for adaptive training of the Time Domain Equalizer (MLC-TEQ) and may be used to obtain Finite Impulse Response (FIR) filter coefficients for Time domain Equalizer (TEQ) used in Discrete Multitone (DMT) based applications.

### FIELD OF THE INVENTION

The present invention relates generally to time domain equalizer filters (TEQ) used in digital communications systems, including discrete multi-tone (DMT), duplex systems, with equipment such as modems, customer premises equipment (CPEs), central office (CO) equipment, etc. The invention is used in physical layer applications and may be used in conjunction with other filters, such as echo cancellers. The invention is for use in many applications including with systems using asymmetric transmit and receive rates, e.g., ADSL, VDSL, etc., and in conjunction with a number of higher layer protocols, such as ATM, VoIP, VoDSL, etc. The present invention may further involve a minimum mean square error linearly constrained fast algorithm for adaptive training of time domain equalizers.

### BACKGROUND OF THE INVENTION

The advent of the Internet and the widespread popularity of personal computers have created an unprecedented demand for high bandwidth networks. Generally, Internet applications, from simple email to real time video conferencing, from web surfing to interactive movies, from interactive games to virtual TV stations, from online trading to online gambling, demand a higher bandwidth communication network. A fundamental challenge for the communication industry is to provide a reliable and affordable high bandwidth communication link to all types of Internet users. Various competing wire-line, wireless, and optical broadband technologies are deployed to partially meet the ever-increasing demand for higher bandwidth. The fastest growing broadband technology is the Digital Subscriber Line (DSL) technology, which provides a high bandwidth always-on connection over standard twisted pair copper media of the conventional telephone network. Among other wire-line media, coaxial cables are capable of providing always-on connections, however, its presence is insignificant compared to millions and millions of wired telephone customers who are connected by a twisted pair of copper wires. Other technologies, such as satellite, wireless, and optical, either provide limited coverage, limited bandwidth, or are too expensive for deployment to individual customers. As a result, DSL technology is uniquely positioned to provide the broadband link between individual customer premise and the central office, the so-called last-mile of the high-bandwidth communication network.

DSL is the fastest growing among emerging broadband technologies for very good reasons. First of all, DSL utilizes the existing copper wire network infrastructure. Secondly, compared to the voice modems, such as V.34 and V.90, used in most personal computers that provide up to 56 kbps dial-up connection, DSL provides a high bandwidth always-on connection with typical connection speeds from 384 kbps to 6 Mbps. Moreover, DSL is affordable with easy installation, simple turn-up, and high service reliability. The successful deployment of DSL is capable of providing digital broadband connection to anyone with an analog telephone line.

DSL services have been standardized over time by regional organizations such as, American National Standard Institute (ANSI), European Telecommunication Standard Institute (ETSI), and by world telecommunication organization International Telecommunication Union (ITU). These DSL standards define data communication protocols to connect customer premise equipment (CPE) to the central office (CO) and to provide connections to various networks, such as DSL service providers, virtual private networks (VPN), or the Internet. Various forms of digital data (e.g., voice, video, and data) can be transported using DSL technology. For transport of voice, DSL equipment is connected to the public switched telephone network (PSTN). For transport of video and data, DSL equipment uses the Internet via an Internet service provider (ISP). Voice over DSL (VoDSL) is capable of providing computer-to-computer, computer-to-telephone, and telephone-to-telephone voice services using an integrated access device (IAD). Video over DSL includes transport of MPEG-1 or MPEG-2 files, video conferencing using Internet Protocol (IP) standard such as ITU H.323, WebCam, and video mail. In addition, DSL supports simple data transport, e.g., bearer services, for virtual private network (VPN), leased data line such as T1 and E1, Point-to-Point Protocol (PPP), Asynchronous transfer mode (ATM), and Internet Protocol (IP).

Like other communication technologies, DSL has gone though a major evolution over the last decade and a collection of technologies, commonly referred to as xDSL, are developed under the umbrella of DSL. One type of subscriber loop digital transmission technology involves an integrated services digital network (ISDN), which has replaced a significant portion of the analog phone lines in Europe and Japan. ISDN offers integrated voice and data services and connection speed up to 144 kbps. Due to the high cost of deployment, an alternative solution called integrated digital loop carrier (IDLC) was deployed in United States. However, resulting data rates were considered inadequate for individual customers. As a result, advanced DSL technologies were developed including HDSL, SDSL, ADSL, HDSL2, SHDSL, and VDSL, all of which are capable of connection speed in excess of lMbps. These advanced DSL technologies were developed to address different needs and application demands, while serving different market segments. For example, SHDSL is a symmetric service designed for long reach office applications with connection speed of 1.5 Mbps, whereas, VDSL is designed to provide a very high-speed asymmetric service for a short-range applications.

DSL systems achieve high bit rates due to an effective application of Digital Signal Processing (DSP) techniques which are enabled by advances in DSP algorithm design and VLSI design, which provides tools to physically implement these techniques and corresponding algorithms. Among the various techniques designed for communication applications, Discrete MultiTone (DMT) provides bit rates close to a maximum achievable level. In fact, due to this property and other properties, DMT has been elected as the line coding technique for the international ADSL standard.

DMT technique deals with the linear distortion caused by channel spread where the channel is divided into smaller channels with no channel spread, thereby minimizing distortion. However, the length of allowable channel spread is limited by a symbol prefix length used by the DMT system. In real life applications, however, the channel length is generally greater than the prefix length and further increases in length as the distance between the CO and the user increases. Therefore, a form of preprocessing received data is useful for shortening the effective channel length seen by the DMT receiver to a length less than or equal to the prefix length. The most common approach, known as Time domain Equalization (TEQ), is to apply a linear filtering to received data samples to shorten the effective channel spread.

In a typical DMT based modem, the TEQ filter is located after the receive filter and before the DMT receiver block. Given this structure, one major concern involves designing an optimal and efficient algorithm to identify TEQ filter taps such that a requirement in the channel length is satisfied. Ultimate optimization goal involves maximizing data communication rate of the DMT system. However, designing TEQ filters to directly satisfy this goal is not practically implementable due to high computational complexity. Therefore, it is desirable to develop algorithms for obtaining TEQ coefficents which are lower in complexity and which provide a high bit rate.

### SUMMARY OF THE INVENTION

Aspects of the present invention overcome the problems noted above, and realize additional advantages. One aspect of the invention provides a method and system to obtain Finite Impulse Response (FIR) filter coefficients for Time Domain Equalization (TEQ) for use in applications, such as Discrete Multi-tone (DMT) based applications, including asymmetric modes such as ADSL, VDSL, etc. The TEQ filter coefficients obtained by use of the invention shortens the overall effective discrete time channel impulse response length (hₖ>>zₖ) within a given target length (symbol/packet prefix length for DMT applications). Two key advantages, for example, of the invention are: 1) providing a TEQ filter with near optimal performance; and 2) facilitates adaptive implementation on a real system, an example of such an implementation is discussed elsewhere herein. Moreover, additional aspects of the invention include: a hypothetical target impulse response (TIR) vector, representing the combined response of the transmission channel and TEQ filter, may be used as the search vector; one element, any element, of the TIR vector is constrained to be equal to a constant; the error is computed by using the difference between the TEQ output and the hypothetical TIR filter output and is minimized to lessen the residual energy of the overall channel outside the target length; TEQ filter coefficients may be computed by minimizing the mean square error (MSE) criterion; and a family of TEQ vectors may be parameterized by two quantities, the location of the constrained element of the TIR vector and the delay value used in the computation. The TEQ filter coefficients obtained as a result of the invention minimize energy ISI and ICI and yields a higher bit rate.

In another manner, the present invention implements a minimum mean square error linearly constrained fast algorithm for adaptive training of time domain equalizers. One aspect of this invention relates to a minimum mean square error linearly constrained fast algorithm for adaptive training of a Time Domain Equalizer (MLC-TEQ) is provided. A fast adaptive algorithm of the present invention may be used to obtain Finite Inpulse Response (FIR) filter coefficients for Time domain Equalizer (TEQ) used in Discrete Multitone (DMT) based applications, such as ADSL, for example. The TEQ coefficients obtained by the algorithm of the present invention shortens the overall effective discrete time channel impulse response length within a given target length (e.g., symbol prefix length for DMT application). Advantages of the proposed data aided adaptive algorithm may include providing the TEQ filter coefficients with near-optimal performance; having low computational requirements, having fast convergence, and exhibiting attractive stability properties. Other advantages may also be realized by the present invention and variations thereof.

According to an embodiment of the present invention, a method for implementing a fast adaptive algorithm for obtaining finite impulse response filter coefficients for a time domain equalizer filter comprises the steps of adaptively computing at least one equalization delay parameter; and adaptively computing at least one time domain equalizer filter coefficient based on the equalization delay parameter.

Other aspects of the present invention may include an overall channel impulse response length shortened within a given target length; the step of computing an estimate cross-correlation function; the step of defining a variable as an argument maximizing an absolute value of the cross-correlation function wherein the variable represents a peak location for the absolute value of the cross-correlation function; the step of selecting an equalization delay as a function of the variable; the step of minimizing mean square error criterion; the step of implementing one or more of training sequences and received sequences; wherein the training sequences comprise consecutive samples of a received signal; wherein the time domain equalizer filter is a sample spaced finite impulse response filter; wherein the time domain equalizer filter is a fractionally spaced finite impulse response filter; and wherein the time domain equalizer filter minimizes one or more of energy inter symbol interference and inter channel interference.

According to another embodiment of the present invention, a system for implementing a fast adaptive algorithm for obtaining finite impulse response filter coefficients for a time domain equalizer filter comprises a delay module for adaptively computing at least one equalization delay parameter and an equalizer module for adaptively computing at least one time domain equalizer filter coefficient based on the equalization delay parameter.

Other aspects of the present invention may include an overall channel impulse response length shortened within a given target length; a cross-correlation module for computing an estimate cross-correlation function; a defining module for defining a variable as an argument maximizing an absolute value of the cross-correlation function wherein the variable represents a peak location for the absolute value of the cross-correlation function; a selection module for selecting an equalization delay as a function of the variable; a minimizing module for minimizing mean square error criterion; an implementing module for implementing one or more of training sequences and received sequences; wherein the training sequences comprise consecutive samples of a received signal; wherein the time domain equalizer filter is a sample spaced finite impulse response filter; wherein the time domain equalizer filter is a fractionally spaced finite impulse response filter; and wherein the time domain equalizer filter minimizes one or more of energy inter symbol interference and inter channel interference.

### BRIEF DESCRIPTION OF THE DRAWINGS

The present invention can be understood more completely by reading the following Detailed Description of the Invention, in conjunction with the accompanying drawings, in which:

FIG. 1a is a block diagram illustrating a digital echo canceller, according to an embodiment of the present invention.

FIG. 1b is a system diagram illustrating a digital echo canceller implementation, according to an embodiment of the present invention.

FIG. 1c is a system diagram illustrating a TEQ implementation, according to an embodiment of the present invention.

FIG. 1d is a system diagram illustrating modem transmission, according to an embodiment of the present invention.

FIG. 2 is a block diagram illustrating an echo canceller, according to an embodiment of the present invention.

FIG. 3 is a block diagram illustrating an example of a dual rate echo canceller, according to an embodiment of the present invention.

FIG. 4 is a block diagram illustrating an example of a dual rate echo canceller, according to an embodiment of the present invention.

FIG. 5 is a block diagram of a CPE side dual rate echo canceller for simultaneous support of multiple annexes, according to an embodiment of the present invention.

FIG. 6 is an example of an impulse response of IF and AAF, according to an embodiment of the present invention. FIG. 7 is a convolution of IF and AAF impulse response, according to an embodiment of the present invention.

FIG. 8 is a block diagram illustrating an example of a weighted vector error echo canceller, according to an embodiment of the present invention.

FIG. 9 is a flowchart illustrating an update process, according to an embodiment of the present invention.

FIG. 10a is a block diagram of a TEQ system, according to an embodiment of the present invention illustrating a fractionally spaced TEQ.

FIG. 10b is a block diagram of a TEQ system, according to an embodiment of the present invention illustrating a sample spaced TEQ.

FIG. 10c is a block diagram of a TEQ system, according to an embodiment of the present invention illustrating a hypothetical model of a delay sample transmit signal for determining TEQ filter coefficients.

FIG. 11 presents a flow chart of the method in accordance with the current invention.

FIG. 12 presents a flow chart describing a method of calculating the TEQ filter vector of the present invention.

FIG. 13 presents a flow chart of the steps of calculating TIR ({bₖ}) and TEQ ({wₖ}) filter coefficients using MLC-TEQ.

FIGS. 14a and 14b are schematic diagrams of hardware architectures in which the inventive aspects of the present invention may be incorporated.

FIG. 15 is a block diagram of a physical media dependent layer of a ADSL CPE chip in which the inventive aspects of the present invention may be incorporated.

FIG. 16 is a block diagram of a transmission convergence layer of a ADSL CPE chip in which the inventive aspects of the present invention may be incorporated.

FIG. 17 is a block diagram of an analog front end device in which the inventive aspects of the present invention may be incorporated.

FIGS. 18a-18c are block diagrams of applications in which the inventive aspects of the present invention may be incorporated.

List of Acronyms

A/D—Analog To Digital

AAF—Anti-Aliasing Filter

ADC—Analog to Digital Converter

ADSL—Asymmetric Digital Subscriber Line

AECF—Adaptive Echo Cancellation Filter

AFE—Analog Front End

AGC—Automatic Gain Control

AOC—ADSL Overhead Control

ANSI—American National Standard Institute

ARM—Advanced RISC Machine

ASIC—Application-Specific Integrated Circuit

ATM—Asynchronous Transfer Mode

BIU—Bus Interface Unit

CIR—Channel Impulse Response

CLECs—Competitive Local Exchange Carriers

CLK—Clock

CO—Central Office

CPE—Customer Premise Equipment

CRC—Cyclic Redundancy Check

CRL—Clock Recovery Loop

CSR—Control and Status Registers

DAC—Digital to Analog Converter

D/A—Digital To Analog

dB—Decibels

DMA—Direct Memory Access/Addressing

DMT—Discrete Multi-Tone

DP—DMT Processor

DSB—Down Sampling Block

DSL—Digital Subscriber Line

DSLAM—DSL Access Multiplexor/Module

DSP—Digital Signal Processing

EEPROM—Electrically Erasable Programmable Read Only Memory

EC—Echo Canceller

ECF—Echo Cancellation Filter

EOC—Embedded Overhead Control

EPB—External Peripheral Bus

Eth PHY—Ethernet Physical Layer

ETSI—European Telecommunication Standard Institute

EWMP—Error Weighting Multi-input-multi-output Filter

FDD—Frequency Division Duplex

FEC—Forward Error Correction

FEQ—Frequency Domain Equalization

FIFO—First In First Out

FIR—Finite Impulse Response

GPIO—General Purpose Input/Output

HDLC—High-Level Data Link Control

HDSL—High-Speed Digital Subscriber Line

HIU—Host Interface Unit

IAD—Integrated Access Device

ICE—Information and Content Exchange

ICE—In-Circuit Emulator

ICI—Inter Channel or Carrier Interference

IDLC—Integrated Digital Loop Carrier

IF—Interpolation Filter

I/F—Interface

IFB—Interpolation Filter Bank

IFFT—Inverse Fast Fourier Transform

ILECs—Incumbent Local Exchange Carriers

IP—Internet Protocol

IPF—Interpolation Filter

ISDN—Integrated Services Digital Network

ISI—Inter Symbol Interference

ISOS—Integrated Software on Silicon

ISP—Internet Service Provider

ITU—International Telecommunications Union

IXCs—Interexchange Carriers

JEDEC—Joint Electronic Device Engineering Counsel

JTAG—Joint Test Action Group

LD—Line Driver

LMS—Least Mean Square

LPF—Low Pass Filter

LTI—Linear Time-Invariant

MAC—Media Access Control

MCM—Multi Chip Module

MII—Media Independent Interface

MIPS—Million Instructions Per Second

MIMO—Multi-Input Multi-Output

MMSE—Minimum Mean Squared Error

MSE—Mean Squared Error

NP—Network Processor

NTR—Network Timing Reference

OAM—Operation, Administration and Maintenance

OSI—Open Source Initiative

PAC—Programmable Attenuation Control

PCI—Peripheral Component Interconnect

PGA—Programmable Gain Amplifier

PHY—Physical Layer Device

PMS—Physical Media Specific

PP—Protocol Processor

PPP—Point-to-Point Protocol

PROM—Programmable Read Only Memory

PSD—Power Spectral Density

PSTN—Public Switched Telephone Network

RCDR-EC—Reduced Complexity Dual Rate Echo Canceller

RMB—Rate Matching Block

RMB-RT—Rate Matching Block from Receive to Transmit

RMB-TR—Rate Matching Block from Transmit to Receive

ROM—Read Only Memory

RS—Reed Solomon

RSIF—Reference Signal Interpolation Filter

Rx—Receive

SD—Sigma-Delta

SDRAM—Synchronous Dynamic Random Access Memory

SNMP—Simple Network Management Protocol

SNR—Signal To Noise Ratio

SRAM—Static Random Access Memory

STM—Synchronous Transfer Mode

SVD—Singular Value Decomposition

TC—Transmission Convergence

TEQ—Time Domain Equalizers

TIR—Target Impulse Response

Tx—Transmit

UART—Universal Asynchronous Receiver Transmitter

USB—Up Sampling Block

USB—Universal Serial Bus

VCXO—Voltage Controlled Crystal Oscillator

VDSL—Very High Bit Rate Digital Subscriber Line

VoDSL—Voice over Digital Subscriber Line

VoIP—Voice over Internet Protocol

VPN—Virtual Private Network

VU—Vectorization Unit

WEVE-EC—Weighted Vector Error Echo Canceller

### DETAILED DESCRIPTION OF THE INVENTION

The following description is intended to convey a thorough understanding of the invention by providing a number of specific embodiments and details involving echo cancellers. It is understood, however, that the invention is not limited to these specific embodiments and details, which are exemplary only. It is further understood that one possessing ordinary skill in the art, in light of known systems and methods, would appreciate the use of the invention for its intended purposes and benefits in any number of alternative embodiments, depending upon specific design and other needs.

According to an embodiment of the present invention, a dual rate echo canceller is provided for applications with asymmetric transmit and receive rates. In particular, the present invention provides Reduced Complexity Dual Rate Echo Canceller (RCDR-EC) architecture along with low complexity Least Mean Square (LMS) update rules. According to one aspect, the present invention is directed to an echo canceller that provides rate matching functionality for applications (e.g., ADSL, VDSL, etc.) with asymmetric data rates.

The RCDR-EC architecture and LMS update rules of the present invention provide various features and advantages. For example, RCDR-EC may operate at the lower of the two rates, receive and transmit, requiring less computation per data sample. RCDR-EC implements a significantly smaller length echo cancellation filter (ECF) for achieving the same (or similar) level of echo suppression of conventional implementations. This reduces the hardware requirement for implementation of RCDR-EC. Due, in part, to the reduction in ECF length, RCDR-EC may involve significantly less computation for filtering operation in steady state. The reduced rate and smaller echo canceller length enables RCDR-EC training to be simplified where less computation is required for adaptive training of the RCDR-EC. In addition, inherent out-of-band noise rejection capability of RCDR-EC enables adaptive training to require less time to converge. Moreover, out-of-band noise rejection enables the adaptive training algorithm to yield an improved RCDR-ECF resulting in enhanced echo suppression.

The present invention provides an efficient rate matching echo canceller for applications with asymmetric transmit and receive rates, such as ADSL and VDSL, for example. Another aspect of the present invention provides echo canceller structures for cases involving higher and lower receive rates as compared to the transmit rate. Another aspect of the present invention is directed to developing a low complexity LMS update for adaptive training of the echo cancellation filters. In addition, the present invention reduces hardware requirements for implementation of the echo canceller and reduces computational requirements for steady state operation of the echo canceller. As a result, overall performance of the echo canceller is improved.

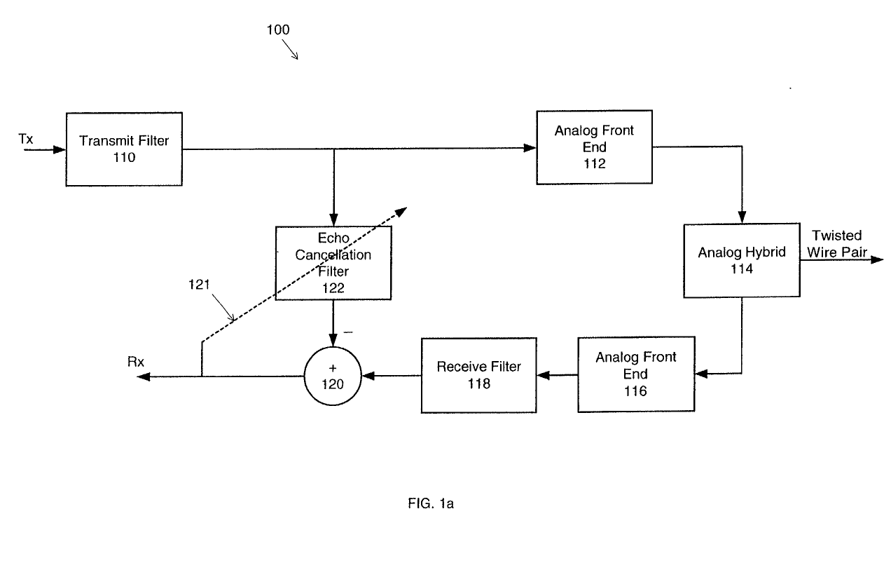

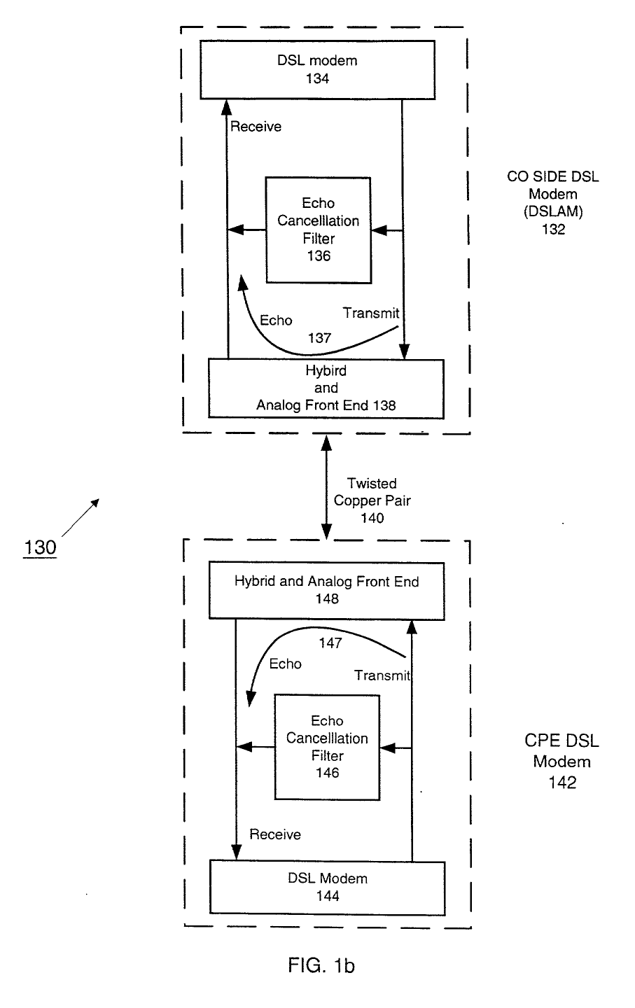

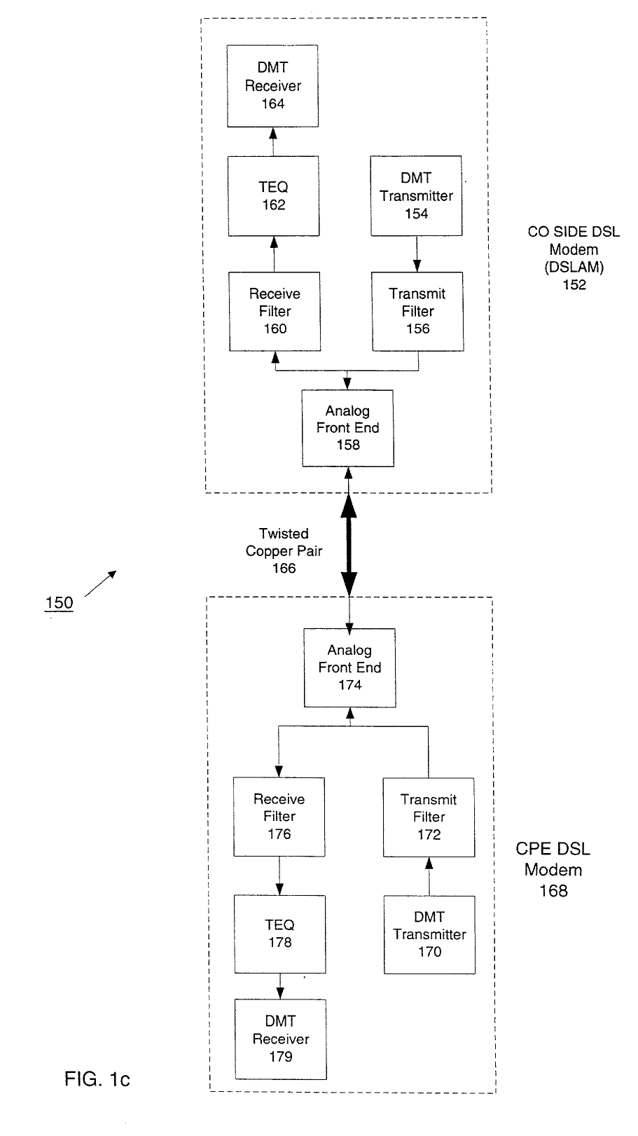

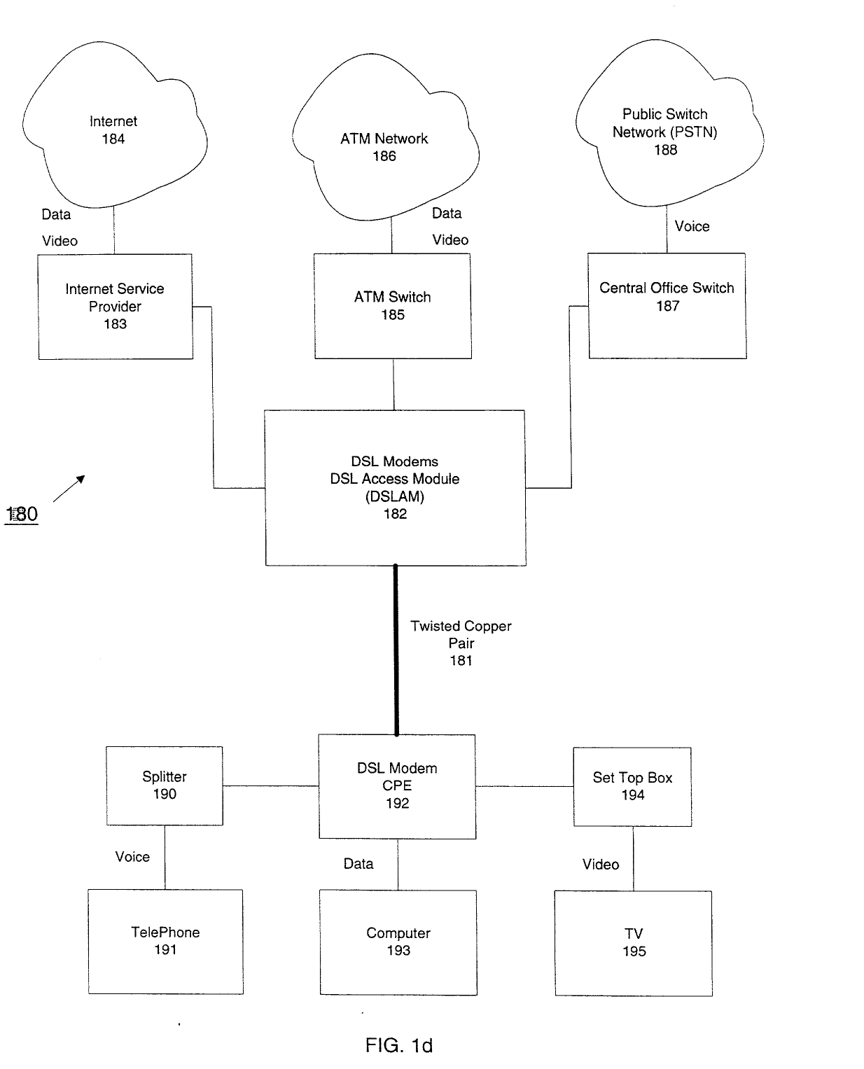

A basic block diagram of the digital echo canceller structure 100, which may be employed in central office (CO), CPE or other equipment, is shown in FIG. 1a. A transmit filter 110 receives an input transmit signal from a transmit path and generates a filtered transmit signal. The output of transmit filter 110 may be received by analog front end (AFE) 112, which is comprised of digital to analog converter and various analog components including line drivers, for example. Echo cancellation filter (ECF) 122 receives an input from the output of the transmit filter and generates a copy of an echo signal by a linear filtering operation. The output generated by AFE 112 may be received at an input of Analog Hybrid 114, which is comprised of various passive analog components, for example, and may be coupled to a twisted wire pair or other transmission line. A receive signal may be received by analog hybrid 114, which may be coupled to AFE 116 at a receive side. For example, analog hybrid 114 may include common analog components, such as resistors and capacitors. The output generated by AFE 116 is received at an input of receive filter 118. The receive filter performs linear filtering operation and attempts to suppress out of band noise. The copy of the echo signal generated by ECF 122 is subtracted from the receive signal generated by receive filter 118, at summer 120. The resulting residual signal may be used to train echo cancellation filter 122, such as by feeding a sampling signal 121 into echo cancellation filter 122.

As shown in FIG. 1a, digital echo cancellation may be achieved by obtaining a reliable copy of the echo signal, which may be generated from the transmit signal using a filter, such as a Finite Impulse Response (FIR) ECF, as illustrated by 122. The copy of the echo signal is then subtracted from the received signal. The FIR ECF 122 operates as a connecting branch between the transmit and receive paths. For example, the echo canceller filter receives an input from the transmit path and generates an output for the receive path. Hence, the ECF 122 accommodates the rate transition from the input transmit rate to the output receive rate. For applications, such as symmetric DSL (e.g., HDSL2, G.shdsl, etc.), where the transmit and receive data rates are identical there is generally little or no need for rate transition. As a result, implementation of ECF is straightforward in these cases. However, for applications such as ADSL and VDSL and for other applications that support asymmetric transmit and receive data rates, rate transition may be required at the ECF. As addressed by the present invention, there are different approaches to achieve the rate transition within the ECF. In accordance with an embodiment of the present invention, ECF 122 may incorporate the inventive features as discussed in detail below.

FIG. 1b is a system diagram illustrating a digital echo canceller implementation, according to an embodiment of the present invention. In particular, system 130 illustrates echo cancellation functionality in a DSL modem system. CO side DSL modem is represented by 132, which may include a DSL modem 134 transmitting to and receiving from Hybrid and Analog Front End 138. Echo cancellation filter 136 compensates for a portion of the transmit signal that is received as an echo signal as shown by arrow 137. CO side DSL modem 132 may be connected to CPE DSL modem 142 by a twisted copper pair 140. CPE DSL modem 142 may include a DSL modem 144 transmitting to and receiving from Hybrid and Analog Front End 148. Echo cancellation filter 146 compensates for a portion of the transmit signal that is received as an echo signal as shown by arrow 147. The inventive aspects of the echo cancellation filter as described in detail below may be incorporated into echo cancellation filter represented by 136 and 146.

FIG. 1c is a system diagram illustrating a TEQ implementation, according to an embodiment of the present invention. In particular, system 150 represents TEQ in a DMT based DSL modem. CO Side DSL Modem 152 may include DMT transmitter 154, Transmit Filter 156, Analog Front End 158, Receive filter 160, TEQ 162 and DMT receiver 164. CO Side DSL Modem 152 is coupled to CPE DSL modem 168 via twisted copper pair 166. CPE DSL modem 168 may include DMT transmitter 170, Transmit Filter 172, Analog Front End 174, Receive filter 176, TEQ 178 and DMT receiver 179. The inventive aspects of the TEQ features as described in detail below may be incorporated into TEQ represented by 162 and 178.

FIG. 1d is a system diagram illustrating modem transmission, according to an embodiment of the present invention. At the CO end, various sources of data may be transmitted via a DSL modem, as represented by 182, which may further include DSL Access Module, DSLAM, for example. Internet 184 may provide data, such as video and other forms of data, via Internet Service Provider 183. ATM Network 186 may provide data, such as video and other forms of data, via ATM Switch 185. Public Switch Network (PSTN) 188 may provide voice data to Central Office Switch 187. DSL modem 182 may receive the various forms of data and communicate via a twisted copper pair 181 at a CPE device. At the CPE end, data from DSL modem 182 may be received by DSL modem CPE 192. Voice data may be received by splitter 190 for transmission to a telephone 191 or other voice device. DSL modem CPE 192 may transmit data to a computer 193 or other device. Video data may be received by set top box 194 for transmission to television (TV) 195 or other video device. The inventive aspects of the echo cancellation features as well as the TEQ features may be incorporated in this system, in accordance with the various embodiments of the present invention as discussed in detail below.

Generally, the receive data rate is a rational multiple of the transmit data rate, as illustrated by

Rᵣₓ=αRₜₓ,

where α=P/Q for co-prime integers P and Q (e.g., P and Q do not have any common factors). Rₜₓ and Rᵣₓ represent the sampling rates at the output of the transmit and the receive filters, respectively. In one example, α>1 may represent cases, such as ADSL CPE, where the receive rate is higher than the transmit rate. On the other hand, α<1 may represent cases, such as ADSL CO, where the receive rate is lower than the transmit rate. Depending on the value of α, different Reduced Complexity Dual Rate Echo Canceller (RCDR-EC) structures may be implemented.

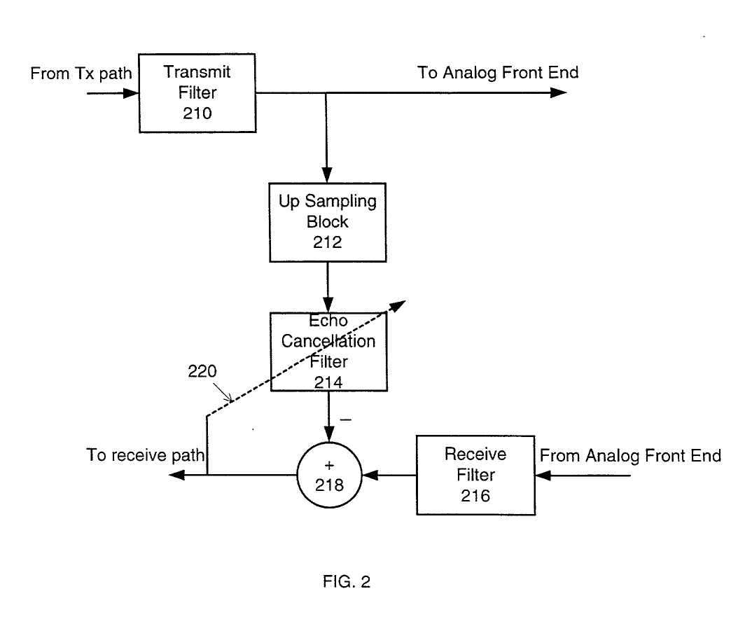

FIG. 2 is a block diagram of an echo canceller, according to an embodiment of the present invention. Sampling may occur by rate matching as represented by 220. In one example, FIG. 2 represents an echo canceller for applications where the receive rate is higher than the transmit rate. A transmit filter 210 may receive a transmit signal and generate a filtered transmit signal. The output of the transmit filter 210 may be coupled to an analog front end or other device. A copy of an echo signal associated with the transmit signal may be up-sampled by Up Sampling block 212 to match the sample rate to the receive rate. The up-sampled signal may then be received by Echo Cancellation Filter 214 to produce an output at the receive rate. The resulting output may be subtracted from a received signal filtered by Receive filter 216. Conventional echo cancellers generally operate the ECF at the higher receive rate. As a consequence, the ECF, which may be a Finite Impulse Response (FIR), may require a larger number of taps to span a fixed length of time. As a result, extra hardware or software complexities will result. In accordance with the present invention, Echo Cancellation Filter 214 may include the inventive aspects of the invention, as discussed in detail below.

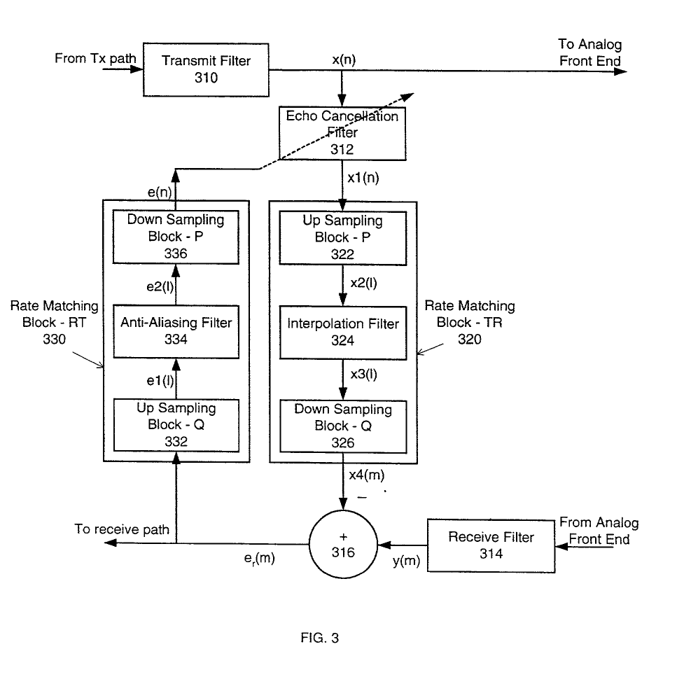

FIG. 3 illustrates a block diagram of a Reduced Complexity Dual Rate Echo Canceller (RCDR-EC), according to an embodiment of the present invention. In particular, FIG. 3 illustrates a case where the receive rate is higher than the transmit rate. As shown in FIG. 3, a transmit filter 310 may receive a transmit signal from a transmit path and generate a filtered transmit signal x(n). Transmit filter 310 may operate at a transmit rate (Rₜₓ). The output x(n) of the transmit filter 210 may be received by an analog front end or other device. Echo Cancellation Filter (ECF) 312 may include an adaptive FIR filter that receives an input from the transmit path and generates a copy of an echo associated with the transmit signal, as shown by x1(n). ECF 312 may operate at transmit rate (Rₜₓ). Since both the input and output of ECF 312 are sampled at the lower transmit rate (Rₜₓ), the ECF 312 operates at the lower transmit rate (Rₜₓ).

Rate Matching Block from Transmit to Receive (RMB-TR) 320 up-samples the output x1(n) of ECF 312 by a factor α with appropriate filtering wherein α=P/Q. The RMB-TR 320 may further include sub blocks, such as an Up Sampling Block (USB-P) 322 with up sampling factor P, an Interpolation Filter (IPF) 324, and a Down Sampling Block 326 (DSB-Q) with down sampling factor Q. Other sub-blocks may be implemented.

An output x1(n) of the ECF 312 may be received by the USB-P 322. An up sampling function at the USB-P 322 may be achieved by a zero filling operation, e.g., the USB-P inserts P−1 zeros between consecutive input signal samples. Other operations for achieving up sampling may be implemented. Thus, USB-P 322 may generate samples P times faster than the input sample rate Rₜₓ.

An output x2(l) of the USB-P 322 may be received by the IPF 324. The IPF 324 may include a fixed FIR filter that interpolates the up-sampled signal. Essentially, IPF 324 may serve as a low pass filter for filtering out most or all P−1 replicas of the transmit signal generated from the up sampling function. The IPF 324 may operate at P times the transmit rate Rₜₓ or other variation thereof.

An output x3(l) of the IPF 324 may be received by the DSB-Q 326. The DSB-Q 326 may down sample the output of the IPF 324 by a factor Q by dropping Q−1 samples from the input data stream and generating a signal at the receive rate Rᵣₓ.

An incoming receive signal from an Analog Front End may be received by Receive Filter 314, which operates at a receive rate Rᵣₓ. Receive Filter 314 may then generate a filtered receive signal y(m). The output x4(m) of the RMB-TR 320 may then be subtracted from the filtered receive signal y(m) from Receive Filter 314 at summer 316 to generate a residue echo signal eᵣ(m).

Rate Matching Block from Receive to Transmit (RMB-RT) 330 may down sample the residue echo signal eᵣ(m) by a factor a (or other factor) with appropriate filtering. Similar to RMB-TR 320, the RMB-RT 330 may include sub blocks, such as Up Sampling Block (USB-Q) 332 with up sampling factor Q, an Anti-Aliasing Filter (AAF) 334, and a Down Sampling Block (DSB-P) 336 with down sampling factor P.

The residue echo signal eᵣ(m) may be received by the USB-Q 332. The up sampling at the USB-Q 332 may be achieved by a zero filling operation, e.g., the USB-Q 332 inserts Q−1 zeros between consecutive input signal samples. Other operations for achieving up sampling may be implemented. Thus, USB-Q 332 may generate samples Q times faster than the input sample rate Rᵣₓ.

An output e1(l) of the USB-Q 332 may be received by the AAF 334. The AAF 334 may include a fixed low pass FIR filter that receives the up-sampled output of the summer 316 and filters out most or all the high frequency signals above the transmit band before feeding it to a down-sampling block. The AAF 334 may operate at Q times the receive rate Rᵣₓ.

An output e2(l) of the AAF 334 may be received by the DSB-P 336. The DSB-P 336 may down sample the output of the AAF 334 by a factor P (or other factor) by dropping P-1 samples from the input data stream and generating an error signal e(n) at the transmit rate Rₜₓ.

In one particular embodiment, for RCDR-EC of the present invention, the up sampling is accomplished after the ECF 312, as opposed to the conventional approach where up sampling is done before EFC 312.

The transmit signal x(n) may first be filtered by a N-tap FIR ECF where

{w₁, w₂, w₃, . w_{N}},

represents N adaptable ECF filter coefficients. The output of the ECF may be written as

$$x1 ( n ) = {\sum }_{k = 1}^{N} x ( n - k + 1 ) {w}_{k} = {x}_{n}^{T} w ,$$

where xₙ is the data vector

xₙ [x(n), x(n−1), x(n−2), . . . x(n−N+1)]^{T},

w is the coefficient vector,

w [w₁, w₂, w₃, . . . w_{N}]^{T},

and T denotes the transpose operation.

According to another embodiment of the present invention, the RMB-TR 320 may up-sample x1(n) by a factor α. For example, for every P input samples the RMB-TR 320 may generate Q output samples where α=P/Q. As discussed above, the up sampling at the USB-P 322 may be achieved by a zero filling operation. Other operations for achieving up sampling may be implemented. The output x2(l) of the USB-P 322 may be expressed as

$$x2 ( l ) = \{ \begin{matrix}x1 ( n ) , & if l = Pn \\ 0 & otherwise\end{matrix}$$

In other words, x2(l) may include the samples of x1(n) with P−1 zeros inserted in between, e.g., samples of x2(l) may be given as follows:

$$⋯0 , x1 ( n - 1 ) , \underbrace{0 , 0 , ⋯ , 0}_{P - 1 zeros} , x1 ( n ) , 0 , ⋯$$

Different time indices may be used to represent different sampling rates, e.g., n, l, and m may be used to represent rates Rₜₓ, PRₜₓ (or equivalently, QRᵣₓ), and Rᵣₓ, respectively, for example.

The output of a N_{f} tap FIR IPF 324 may be given by

$$x3 ( l ) = {\sum }_{k = 1}^{{N}_{f}} x2 ( l - k + 1 ) {f}_{k} ,$$

where

{f₁,f₂,f₃, . . . f_{Nf}}

represent the N_{f} IPF coefficients.

The output x3(l) of the IPF 324 may be down sampled using DSB-Q 326 where the output may be represented by

x4(m)=x3(l), where l=Qm.

In other words, x4(m) may include decimated samples of x3(n), where the samples of x4(n) may be written as

. . . , x3(Q(l−1)), x3(Ql), x3(Q(l+1)), . . .

The output of RMB-TR 320 may be subtracted from the incoming receive signal y(m) from 314 to generate the residue echo signal eᵣ(m), which may be defined as

eᵣ(m)=y(m)−x4(m).

The residue echo signal eᵣ(m) may be up-sampled by USB-Q 332 by zero filling (or other operation) where the output may be given by

$$e1 ( l ) = \{ \begin{matrix}{e}_{r} ( m ) , & if l = Qm \\ 0 & otherwise .\end{matrix}$$

The up-sampled signal e1(l) may be filtered by the AAF 334, which may be a FIR filter, to generate the filtered version e2(l), which may be expressed as

$$e2 ( l ) = {\sum }_{k = 1}^{{N}_{g}} e1 ( l - k + 1 ) {g}_{k} ,$$

where

{g₁, g₂, g₃, . . . g_{Ng}}

are a Ng AAF coefficients.

The output e2(l) of the AAF 334 may be down sampled using DSB-P 336 to generate the error signal e(n) which may be defined as

e(n)=e2(l), where l=Pn.

IPF 324 and/or AAF 334 may include low pass filters that filter out the high frequency signals above the transmit band. According to an embodiment of the present invention, the same (similar or related) coefficients may be used for both IPF and AAF, e.g., fₖ=gₖ for all k. Also, the samples of the error signal may be generated at the transmit rate Rₜₓ. The error signal e(n) may then be used to adaptively train the coefficients of ECF 312, as discussed below.

To describe the LMS update rules for the RCDR-EC structure of the present invention, the error signal e(n) may be expressed in terms of the transmit signal x(n) and the receive signal y(m) as well as IPF and AAF coefficients. For example, the error signal e(n) may be written as

e(n)=yᵣ(n)−h^{T}Xₙw,

where yᵣ(n) is the received signal component after USB-Q 332, AAF 334, and DSB-P 336, w is the ECF coefficient vector,

$${X}_{n} [ \begin{matrix}x ( n ) & x ( n - 1 ) & … & x ( n - N + 1 ) \\ x ( n - 1 ) & x ( n - 2 ) & … & x ( n - N ) \\ ⋮ & ⋮ & ⋮ & ⋮ \\ x ( n - L + 1 ) & x ( n - L ) & … & x ( n - L - N + 2 )\end{matrix} ]$$

is the L×N input data matrix, and

h [h₁, h₂, h₃, . . . h_{L}]^{T},

is the filter coefficients vector that represents the combined effect of IPF 324 and AAF 334 along with the effects of USB-P 322, DSB-Q 326, USB-Q 332, and DSB-P 336.

The DSB-Q 326 and USB-Q 332 may have a sub-sampling effect on the IPF 324 and AAF 334 coefficients, e.g., the equivalent filters may include one of the possible Q phases of the original filters. For example, fₖ^{Q} may denote one of possible Q phases of the IPF filter 324, where

fₖ^{Q}=f_{Q(k-1)+q1}, for k=1, 2, . . . N_{f}^{Q},

In addition, q₁χ1, 2, 3, . . . , Q denotes the selected phase where N_{f}^{Q} is the smallest integer not less than N_{f}/Q. Similarly, for the AAF coefficients,

gₖ^{Q}=g_{Q(k-1)+q1}, for k=1, 2, . . . N_{g}^{Q}

where q₂χ1, 2, 3, . . . , Q denotes the selected phase and N_{g}^{Q} is the smallest integer not less than N_{g}/Q.

The (N_{f}^{Q}+N_{g}^{Q}−1) coefficients of the combined filter response of the single phase IPF 324 and AAF 334 may be represented by bₗ. For example, bₗ may be obtained by convolving fₖ^{Q} and gₗ^{Q} as follows:

$${b}_{l} = {\sum }_{k} {f}_{k}^{Q} {g}_{l - k + 1}^{Q} , for l = 1 , 2 , … , {N}_{f}^{Q} + {N}_{g}^{Q} - 1.$$

From the combined filter coefficients bₗ, the elements of h may be easily obtained. The effect of USB-P 322 and DSB-P 336 may include the selection of a phase out of possible P phases. In other words,

hₗ=b_{P(l-1)+p}, for l=1,2, . . . L,

where pχ1, 2, 3, . . . , P denotes the selected phase and L is the smallest integer not less than (N_{f}^{Q}+N_{g}^{Q}−1)/P. Though the exact value of p, q₁, and q₂ may not significantly impact the performance, the a priori knowledge of these integers may be used to calculate h. In the equations, the value in parenthesis generally refers to the time and variables in bold generally refer to arrays (e.g., vec(n) refers to values of the array “vec” at time n).

Once the expression for the error signal e(n) is obtained, the LMS update rule may be given as follows:

wₙ₊₁=wₙ−μe(n)Xₙ^{T}h,

where μ is the LMS step size. Time subscript for wₙ may represent the LMS iteration.

At a first glance, it may appear that the proposed LMS update requires (L+1)N multiplications per iteration where the factor L is due to the vector-matrix product Xₙ^{T}h. However, due to the shift structure of Xₙ, e.g., Xₙ may be a Hankel (or other) matrix, per iteration, N multiplications may be used instead. Hence, the over all computational complexity of the LMS for RCDR-EC may be 2N multiplications per iteration. The multiplication required may be twice that of usual LMS which in comparison requires N multiplications. As a result, there is a savings of filter coefficients by, at least, a factor α. Thus, the computational complexity of the proposed LMS for RCDR-EC of the present invention is lower for α>2.

According to another embodiment of the present invention, a simplified LMS may be implemented to reduce computational complexities by using an approximation on h. In one example, IPF 324 and/or AAF 334 may include low pass filters. Hence, the impulse responses may be similar to a sinc function. In other words, the impulse response has a dominant peak and diminishes in magnitude away from the peak. Moreover, the convolution of two such filters may also exhibit a similar behavior. Variations may be made to h. For example, the largest element of h may be replaced with its sign. In another example, some or the rest of the elements may be set to zero (or other value). Replacing the largest magnitude element by its sign may result in a scaling of h where such scaling may be absorbed in μ. In addition, no approximation may be involved in this step. After such scaling, the remaining elements may have a magnitude less than one, which may then be approximated to zero. With this approximation, the coefficient vector h becomes a vector of zeros except one non-zero element (e.g., ±1). Without loss of generality, the largest magnitude element of h may be positive and the matrix-vector product may reduce to a delayed version of the input vector, e.g.,

$${X}_{n}^{T} \hat{h} = [ \begin{matrix}x ( n - d ) \\ x ( n - d - 1 ) \\ ⋮ \\ x ( n - d - N + 1 )\end{matrix} ] ,$$

where ĥ is the approximate h and d is the index of the largest element of h.

Using this approximation, the LMS update may simplify to,

wₙ₊₁=wₙ−μe(n)x_{n-d},

where xₙ is the data vector defined before as

xₙ=[x(n), x(n−1), x(n−2), . . . x(n−N+1)]^{T}.

Hence, the simplified LMS update for RCDR-EC may be similar to the normal LMS update except for the delay. In other words, the computational complexity of the simplified LMS for RCDR-EC is similar to that of usual LMS.

Since both IPF and AAF are part of the system design, the approximation does not restrict the use of the simplified LMS. The IPF and AAF may be defined such that the resulting combined filter has a single dominant coefficient. Factors that may degrade the convergence and performance of LMS may include multiple dominant peaks in the combined filter response and inexact setting of the delay d, for example.

Since up sampling in the USB-P may be performed by zero filling, the sub blocks of RMB-TR 330 may be combined for efficient poly-phase implementation. The poly-phase implementation of RMB-TR may require RᵣₓN_{f}/P (or equivalently, RₜₓN_{f}/Q) multiplications per second. Efficient poly-phase structure may also be used for RMB-RT 330 and the number of multiplications that may be required per second is RₜₓN_{g}/Q.

Various comparisons may be made between a conventional echo canceller and the RCDR-EC of the present invention for the case α>1, for example.

As for structural differences, a conventional echo canceller is generally composed of an up sampling block followed by an adaptive FIR ECF that operates at the higher receive rate Rᵣₓ. In contrast, in the RCDR-EC approach of the present invention the adaptive FIR ECF may operate at the lower transmit rate Rₜₓ. A rate matching block RMB-TR 330 may be used to generate echo samples at the receive rate and another rate matching RMB-RT 320 may be used to calculated the error signal at the transmit rate.

As for filter lengths, to capture the same (or similar) fixed amount of time span (e.g., echo tail), the RCDR-EC of the present invention may use N filter taps as compared to the αN taps required by the conventional echo canceller approach. However, in addition to the ECF, RCDR-EC of the present invention may implement additional filters, which may include IPF and AAF. In general, the ECF is longer than the combined length of IPF and AAF. Hence, there is a significant reduction in the number of filter taps. For example, for a typical value of N=256 and α=8, the conventional filter requires approximately 2048 taps. According to an example of the present invention, even with two 64 taps IPF and AAF filters, the number of taps for RCDR-EC is approximately 384, significantly less than that required by conventional systems.

As for LMS training computations, the computational complexity may be approximately equal (or similar) for the conventional LMS and simplified LMS for RCDR-EC of the present invention. However, since the conventional ECF is α times longer than that of RCDR-EC of the present invention, the number of multiplications required for LMS update may be a times higher for conventional echo canceller. Due to the reduction in the filter taps, LMS for RCDR-EC of the present invention has lower complexity then the conventional approach for α>2, according to one example of the present invention.

As for steady state computational complexity, in steady state using efficient poly-phase implementation the total number of multiplications per second that may be required by RCDR-EC is (N+N_{f}/Q+N_{g}Q)Rₜₓ. In contrast, even with efficient poly-phase implementation, the number of multiplications per second required by the conventional echo canceller is at least αNRᵣₓ. In a typical application, the total filter length of IPF and AAF may be considered small compared to the length of the ECF filter, e.g., N_{f}+N_{g}<N. Hence, RCDR-EC of the present invention may reduce the steady state computation by at least a factor of α².

As for improved noise floor level and overall performance, in RCDR-EC the AAF filters out signals above a transmit band before generating the error signal e(n). Thus, the error signal has a reduced contribution from the wide band receive signal which acts as noise for echo cancellers. In a conventional echo canceller, the receive signal, even the part outside of the transmit band, contributes to the error signal. Hence, RCDR-EC of the present invention has a lower noise floor that results in reduced convergence time and improved overall performance of the LMS training algorithm. Other comparisons as well as advantages may be recognized by the present invention and variations thereof.

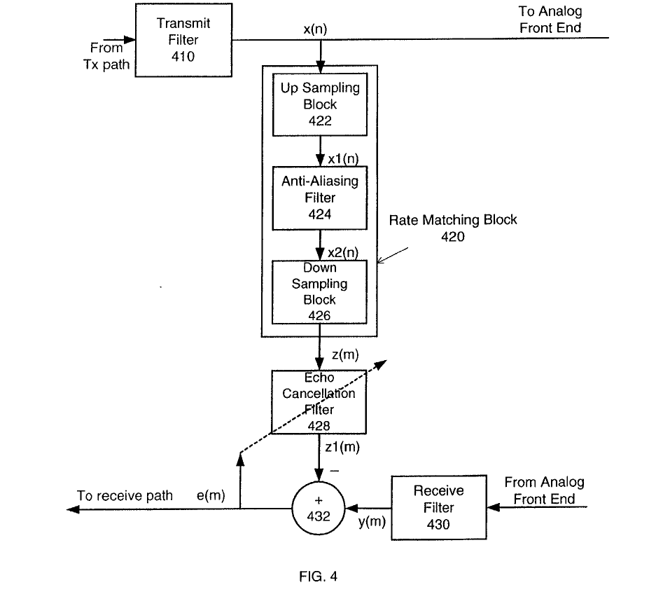

FIG. 4 is a block diagram of a Reduced Complexity Dual Rate Echo Canceller (RCDR-EC), according to an embodiment of the present invention. The block diagram of FIG. 4 may support applications, such as ADSL CO, where the receive rate is lower than the transmit rate, e.g., α<1.

Transmit Filter 410 may receive a transmit signal from a transmit path and generate a filtered transmit signal x(n). The filtered transmit signal x(n) may be an input to an Analog Front End or other device.

Rate Matching Block (RMB) 420 may up-sample the input signal by a factor a (or other factor) with appropriate filtering. The RMB 420 may include sub blocks, such as an Up Sampling Block with up sampling factor P (USB-P) 422, an Anti-Aliasing Filter (AAF) 424, and a Down Sampling Block with down sampling factor Q (DSB-Q) 426.

The filtered transmit signal x(n) may be received by the USB-P 422. The up sampling at the USB-P 422 may be achieved by a zero filling operation, e.g., the USB-P 422 may insert P−1 zeros between consecutive input signal samples. Other operations for achieving up sampling may be implemented. Thus, USB-P 422 generates samples P times faster than the input sample transmit rate Rₜₓ.

An output x1(n) from the USB-P 422 may serve as an input to the AAF 424. The AAF 424 may include a fixed low pass FIR filter that receives the up-sampled signal x1(n) and filters out most or all the high frequency signals above the receive band before feeding it to a down-sampling block. AAF 424 may operate at P times the transmit rate Rₜₓ.

An output x2(n) from the AAF 424 may serve as an input to the DSB-Q 426. The DSB-Q 426 may down sample the output of the AAF 424 by a factor Q by dropping Q−1 samples from the input data stream and generate the output signal z(m) at the receive rate Rₜₓ.

Echo Cancellation Filter (ECF) 428 may include an adaptive FIR filter that receives the down sampled signal z(m) and generates a copy of the echo. Since both the input and output of the ECF 428 are sampled at the lower receive rate (Rᵣₓ), the ECF 428 operates at the receive rate Rᵣₓ. According to an embodiment of the present invention, RCDR-EC provides down sampling before the ECF, wherein ECF operates at the lower receive rate Rᵣₓ.

The transmit signal x(n) may be up-sampled and filtered by the FIR AAF 424 before being down sampled by the DSB-Q 426. The AAF 424 filters out most or all high frequency signals above the receive band. The down sampled signal at the output of the DSB-Q 426 may be denoted by z(m). The down sampled signal z(m) may then be filtered by the ECF 428 where the output of ECF 428 may be expressed as

$$z1 ( m ) = {\sum }_{k = 1}^{N} z ( m - k + 1 ) {w}_{k} = {z}_{m}^{T} w ,$$

where zₘ is the data vector

zₘ [z(m),z(m−1),z(m−2), . . . z(m−N+1)]^{T},

w is the ECF coefficient vector,

w [w₁, w₂, w₃, . . . w_{N}]^{T}.

A receive signal from Analog Front End may be filtered by Receive Filter 430. The output z1(m) of ECF 428 may then be subtracted from the incoming receive signal y(m) to generate error signal e(m), e.g.,

e(m)=y(m)−z1(m).

The samples of the error signal may be generated at the rate Rᵣₓ. This error signal is then used to adaptively train the coefficients of ECF 428 as described in the following section.

According to an embodiment of the present invention, an ECF input z(m) may not be the transmit signal but rather a down sampled version. Thus, to derive the LMS update rule for the RCDR-EC structure of the present invention, the error signal e(m) may be expressed in terms of the down sampled signal z(m), the receive signal y(m), and ECF coefficients as follows:

e(m)=y(m)−zₘ^{T}w,

where y(m) is the received signal, zₙ is the data vector, and w is the ECF coefficient vector as previously discussed.

Once the error signal e(n) has been defined, the LMS update rule may be given as follows:

wₘ₊₁=wₘ−μe(m)zₙ,

where μ is the LMS step size. Time subscript for wₘ may represent the LMS iteration.

The above LMS update rule of the present invention may be similar to a LMS update except for the fact that the data vector is the down sampled version of the transmit signal x(n), for example. Hence, the computational complexity of LMS update for RCDR-EC may be similar as that of the conventional LMS.

According to another embodiment of the present invention, a dual rate echo canceller for simultaneous support of multiple annexes of G.992.1 (or ITU G.dmt) is provided. Other annexes and variations thereof may also be supported. The present invention provides an efficient Reduced Complexity Dual Rate Echo Chancellor (RCDR-EC) architecture for ADSL CPE for simultaneous support of a plurality of annexes, such as Annex A and Annex B of G.992.1. In addition, low complexity LMS update rules are proposed for adaptive training RCDR-EC.

The RCDR-EC architecture and LMS update rules of the present invention provide various features and advantages. The RCDR-EC structure of the present invention may be designed for digital echo cancellation for full rate ADSL at the CPE, for example. The proposed structure of the present invention may also support a plurality of annexes, such as at least both Annex A and Annex B of ITU Standard G.992.1, also known as G.dmt. Other standards, including wire-line technology, may be supported for added versatility and improved functionality. In addition, RCDR-EC of the present invention may operate at the transmit rate, the lower of the two rates, thereby requiring less computation per data sample.

According to one example, the present invention provides an echo canceller structure for full rate ADSL CPE. Another aspect of the present invention is directed to designing the echo canceller flexible enough to simultaneously support, at least, Annex A and Annex B of G.992.1. Another aspect of the present invention is further directed to obtaining an efficient rate matching echo canceller implementation for full rate ADSL CPE as well as other applications.

For example, the ADSL system, as specified in ITU standard G.992.1, may require full-duplex transmission over a single wire line thereby necessitating the separation of transmit and receive signals at the ADSL transceivers, such as the CPE. Typically, a passive analog circuit, e.g., a hybrid circuit, may be used for this purpose. In any realistic implementation, the transmit signal often leaks into the receive path whenever perfect balance is not achieved in the hybrid circuit. The part of the transmit signal that leaks into the receive path is generally referred to as the echo signal. Even though a four-to-two wire conversion circuit has worked well for telephony application, the echo signal, if not adequately suppressed, may severely degrade the performance of full-duplex ADSL systems. Digital echo cancellers are commonly used at the ADSL transceiver to suppress the echo to an adequate level and to recover the performance loss due to the echo.

ADSL systems support asymmetric transmit and receive data rates, where the echo canceller (EC) implemented in the system may be required to accommodate the rate difference. For ADSL systems, the upstream rate is generally higher than the downstream rate. In other words, for ADSL customer premises equipment the receive rate is generally higher than the transmit rate. In accordance with specifications recommended by the full rate ADSL ITU standard G.992.1, for example, the following may apply:

Rᵣₓ=MRₜₓ,

where M is an integer larger than 1, Rᵣₓ and Rₜₓ are the sample rates of receive and transmit signals, respectively. The transmit bandwidth requirements may be different for region specific Annexes, e.g., Annex A and Annex B of G.992.1, for example, and the value of M may depend on the particular Annex and/or other factors and conditions.

The present invention provides a detailed implementation of Reduced Complexity Dual Rate Echo Canceller (RCDR-EC) structures for simultaneous support of, at least, Annex A and Annex B at the ADSL CPE, for example, as well as other applications. In addition, LMS update rules may be implemented for adaptive training of the RCDR-EC of the present invention.

For ADSL CPE and other applications, where the receive rate is higher than the transmit data rate, the usual approach may involve up sampling the transmit signal to the match the receive rate before echo cancellation. As shown in FIG. 2 above, an up-sampled transmit signal may be filtered by the ECF to produce an output signal at the receive rate.

However, for such implementation, the ECF may operate at the higher receive rate and as a consequence the FIR ECF may require a larger number of taps to span a fixed length of time. Thus, extra hardware or software complexities may be needed. RCDR-EC of the present invention may operate at the lower transmit rate thereby reducing hardware and/or software complexities.

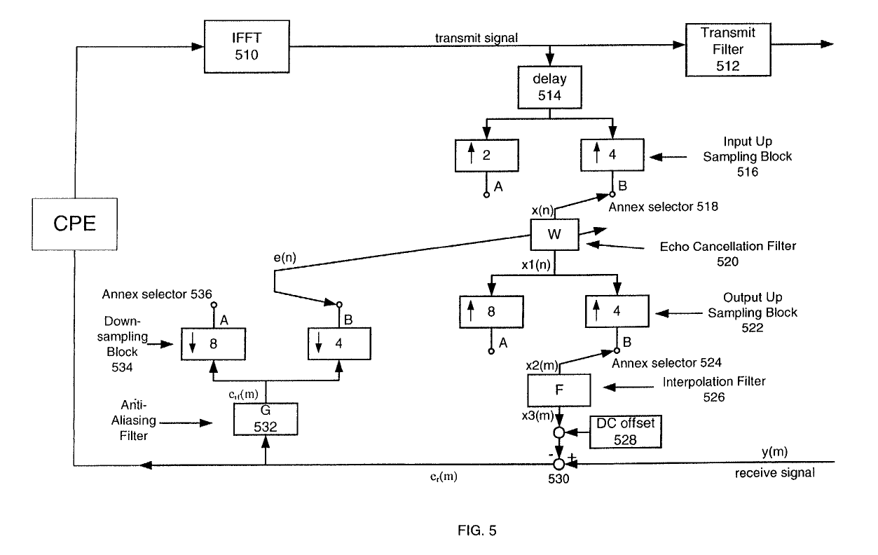

FIG. 5 is a block diagram of a CPE-side echo canceller, according to an embodiment of the present invention. According to one example, the RCDR-EC may include a combination of a delay block 514, an Input Up Sampling Block 516, an Echo Cancellation Filter 520, an Output Up Sampling Block 522, an Interpolation Filter 526, an Anti-Aliasing Filter 532, and a Down Sampling Block 534. In addition, annex selectors 518, 524 and/or 536 may be included as well. An optional DC offset block 528 may be incorporated.

A transmit signal may be received as an input to Inverse Fast Fourier Transform (IFFT) filter 510 for generating a filtered transmit signal. The filtered transmit signal may be received by a Transmit Filter 512. A delay block 514 may receive the transmit signal for generating a delay in the input transmit samples.

According to an embodiment of the present invention, Input Up Sampling Block (USB-I) 516 may up-sample the delayed transmit signal by a factor of 2 or 4 for Annex A and Annex B, respectively. The delayed transmit signal may be up-sampled by other factors as well, which may vary depending on the applications and/or other conditions. The up sampling function may be achieved by zero filling. Other operations may be implemented for achieving the up sampling function. The output rate of the USB-I 516 may be the transmit rate Rₜₓ.

Annex selector 518 may include a number of switches (e.g., three switches) for selecting a variety of annexes (e.g., Annex A or B). As shown in FIG. 5, by way of example, the switch position A and B denotes the respective Annexes. Other selections and/or options may be implemented.

Echo Cancellation Filter (ECF) 520 may include an adaptive FIR filter that receives the up-sampled transmit signal x(n) and generates a copy of the echo, as shown by x1(n). As both the input x(n) and output x1(n) of the ECF 520 may be sampled at the lower transmit rate (Rₜₓ), the ECF filter 520 may operate at the transmit rate Rₜₓ.

Output up sampling block (USB-O) 522 may receive the output x1(n) of the ECF 520 and up-sample x1(n) by a factor of M. For example, the value of M may be 8 for Annex A and 4 for Annex B, where the selection may be made via annex selector 524. Other values of M may be assigned for other options. Other variations may be implemented. The up sampling function may be achieved by zero filling or other operation.

The Interpolation Filter (IF) 526 may be a fixed FIR filter that interpolates the up-sampled signal x2(m). Essentially, the IF 526 may be a low-pass filter that filters out most or all M−1 replica of the transmit signal generated due to up sampling. The IF 526 may operate at the receive rate R, and generate an output x3(m) at the receive rate Rᵣₓ. The output x3(m) of the IF 526 may be subtracted from an incoming receive signal y(m) to generate a residual echo signal eᵣ(m).

Anti-Aliasing Filter (AAF) 532 may include a fixed low pass FIR filter that receives the residual echo signal eᵣ(m) and filters out most or all the high frequency signals above the transmit band before feeding the residual echo signal eᵣ(m) to the down-sampling block (DSB) 534. AAF 532 may operate at the receive rate Rᵣₓ.

Down Sampling Block (DSB) 534 may down sample the output e_{rf}(m) of the AAF 532 by a factor M and generate an error signal e(n) at the transmit rate Rₜₓ. For example, the value of M may be 8 for Annex A and 4 for Annex B, where the selection may be made via annex selector 536. Other values for M may be implemented for other annexes.

For RCDR-EC of the present invention, the up sampling by a factor M (e.g., as performed by USB-O 522) may be performed after the ECF 520 as opposed to the conventional approach where up sampling is performed before the EFC 520.

According to another embodiment of the present invention, the basic signal flow within RCDR-EC may be accomplished as follows: The transmit signal x(n) may be first delayed and then up-sampled. In the absence of the delay block 514, the ECF 520 may contain a leading sequence of zero coefficients, which may result in an inefficient use of the filter coefficients. The leading zero coefficients may attempt to model the delay of the echo signal with respect to the transmit signal caused by various elements in the transmit path and the twisted pair line. The delay block 514 may be added to compensate for this delay of the echo signal and, hence, alleviate the burden for the ECF 520 to model the delay. According to an example of the present invention, the delay block 512 is not an absolute requirement but may be added for improved efficient use of the ECF coefficients.

For example, the highest sub-carrier for Annex A and B may be approximately around 138 and 276 kHz, respectively. As a result, even though the width of the transmit bands may be identical (or similar), Annex B transmit signal may require approximately twice the sampling rate for a passband sampling structure. The input up sampling block (USB-I) 516 along with the annex selector 518 may be used to accommodate various sampling requirements. The output of the WIFT 510 may be sampled at a fixed rate, e.g., 276 ks/s (kilo samples/sec), for example. After the USB-I 516, the transmit sample rates (Rₜₓ) may be approximately equal to 552 ks/s and 1.104 Ms/s for Annex A and B, respectively. The up sampling function may be performed by inserting zeros (e.g., 1 for Annex A and 3 for Annex B) in between consecutive samples of the input signals. Other operations may be used to perform the up sampling function.

The up-sampled transmit signal may then be filtered by a N-tap FIR ECF 520, where x(n) may represent the up-sampled transmit signal and {w₁, w₂, w₃, . . . w_{N}}, may represent N adaptable ECF coefficients. The output of the ECF 520 may then be written as:

$$x1 ( n ) = {\sum }_{k = 1}^{N} x ( n - k + 1 ) {w}_{k} = {x}_{n}^{T} w ,$$

where xₙ is the data vector at time n represented by:

xₙ [x(n), x(n−1), x(n−2), . . . x(n−N+1)]^{T};

w is the coefficient vector represented by:

w [w₁, w₂, w₃, w_{N}]^{T};

and T denotes the transpose operation.

The USB-O 522 may up-sample x1(n) by a factor M. In other words, for every input sample, the USB-O 522 may generate M output samples. As mentioned before, the value of M may depend on (or be related to) the Annex type and/or other factors, e.g.,

$$M = \{ \begin{matrix}8 , & for Annex A \\ 4 , & for Annex B .\end{matrix}$$

The up sampling function may be achieved by a zero filling operation (or other operation) and the output of the USB-O 522 may be expressed as:

$$x2 ( m ) = \{ \begin{matrix}x1 ( n ) , & if m = Mn \\ 0 & otherwise\end{matrix}$$

In other words, x2(m) may include samples of x1(n) with M−1 zeros inserted in between. For example, samples of x2(m) may be expressed as follows:

$$⋯0 , x1 ( n - 1 ) , \underbrace{0 , 0 , ⋯ , 0}_{M - 1 zeros} , x1 ( n ) , 0 , ⋯$$

Different time indices (e.g., n and m) may be used to represent samples with different rates. For Annex A, n may denote a sampling rate of approximately 552 ks/s and for Annex B approximately 1.104 Ms/s. For both Annexes, m may denote a sampling rate of approximately 4.416 Ms/s.

The output of N_{f} tap FIR IF 526 may be represented by:

$$x3 ( m ) = {\sum }_{k = 1}^{{N}_{f}} x2 ( m - k + 1 ) {f}_{k} ,$$

where

{f₁,f₂,f₃, . . . f_{Nf}}

are N_{f} IF 526 coefficients.

The output of IF 526 may be subtracted from the incoming receive signal y(m) to generate the residual echo signal, e.g.,

eᵣ(m)=y(m)−x3(m).

The residual echo signal eᵣ(m) may be filtered by the FIR AAF 532 to generate a filtered version e_{rf}, which may be expressed as:

$${e}_{rf} ( m ) = {\sum }_{k = 1}^{{N}_{g}} {e}_{r} ( m - k + 1 ) {g}_{k} ,$$

where

{g₁, g₂, g₃, . . . g_{Ng}}

are Ng AAF 532 coefficients.

The output of the AAF 532 may be down sampled using DSB 534 by a factor of M to generate the error signal e(n). In this case, the error signal e(n) may be expressed as:

e(n)=e_{rf}(m), where m=Mn.

In other words, e(n) may include decimated samples of e_{rf}(n) where the samples of e(n) may be written as

. . . , e_{rf}(M(n−1)), e_{rf}(Mn),e_{rf}(M(n+1)), . . .

The value of M (e.g., 8 or 4) may be selected by the Annex selector 536.

According to another embodiment of the present invention, the error signal may be used to adaptively train the coefficients of ECF 520.

To describe the LMS update rules for RCDR-EC structure of the present invention, the error signal e(n) may be expressed in terms of the transmit signal x(n), the receive signal y(m), and IF 526 and AAF 532 filter coefficients. The error signal e(n) may be written as:

e(n)=yᵣ(n)−h^{T}Xₙw,

where yᵣ(n) may be the received signal component after AAF 530 and DSB 532, w is the ECF 520 coefficient vector,

$${X}_{n} [ \begin{matrix}x ( n ) & x ( n - 1 ) & … & x ( n - N + 1 ) \\ x ( n - 1 ) & x ( n - 2 ) & … & x ( n - N ) \\ ⋮ & ⋮ & ⋮ & ⋮ \\ x ( n - L + 1 ) & x ( n - L ) & … & x ( n - L - N + 2 )\end{matrix} ]$$

is the L×M input data matrix, and

h [h₁, h₂, h₃ . . . h_{L}]^{T},

is the filter coefficients vector that represents a combined effect of IF 526 and AAF 532 along with effects of USB-O 522 and DSB 534. The (N_{f}+N_{g}−1) coefficients of the combined filter response of IF 526 and AAF 532 may be represented by bₗ. For example, bₗ may be obtained by convolving fₗ and gₗ as follows:

$${b}_{l} = {\sum }_{k} {f}_{k} {g}_{l - k + 1} , for l = 1 , 2 , … , {N}_{f} + {N}_{g} - 1`$$

From the combined filter coefficients bₗ, the elements of h may be easily obtained. The effect of USB-O 522 and DSB 534, in one respect, is to select a phase out of possible M phases. In other words

hₗ=b_{M(l-1)+p}, for l=1,2, . . . , L,

where pχ{0,1,2, . . . , M−1} denotes the selected phase and L may include the smallest integer not less than (N_{f}+N_{g}−1)/M. Though the exact value of p may not significantly impact the performance, an a priori knowledge of p is useful in calculating h.

The LMS update rule may be defined as follows:

wₙ₊₁=wₙ−μe(n)Xₙ^{T}h,

where μ is the LMS step size. The time subscript for wₙ may represent the LMS iteration.

At a first glance, it may appear that the proposed LMS update requires (L+1)N multiplications per iteration. The factor L may be due to the vector-matrix product Xₙ^{T}h. However, due to the shift structure of Xₙ, where Xₙ is a Hankel matrix, for example, per iteration, N multiplications may be required. Hence, the over all computational complexity of the LMS for RCDR-EC of the present invention may be 2N multiplications per iteration. The multiplication required may be approximately twice that of usual LMS which in comparison requires only N multiplications. Since, there is a saving of filter coefficients by a factor M, the computational complexity of the proposed LMS for RCDR-EC of the present invention is lower for at least both values of M=4 or 8.

A simplified LMS may be used to reduce computational complexities by using an approximation on h.

As discussed above, the IF 526 and/or AAF 532 may include low-pass filters. Generally speaking, the impulse responses may be similar to the sinc function. In other words, the impulse response may exhibit a dominant peak and diminish in magnitude away from the peak. Moreover, the convolution of the two such filters may also exhibit a similar behavior. Other types of filters may be used for IF and/or AAF, in accordance with the present invention.

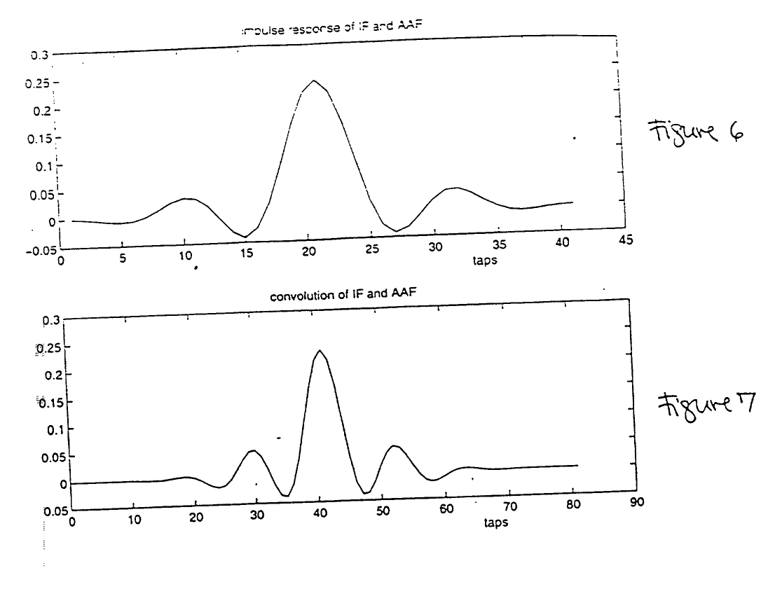

For example, both IF and AAF may include low-pass filters for filtering out the high frequency signals above the transmit band. According to one example, the same (similar or related) coefficients may be used for both IF and AAF, e.g., fₖ=gₖ for all k. For an Annex B application, a 40-tap low pass filter design may be used for at least one of IF and AAF, for example. The impulse response of the 40-tap filter along with the time-domain convolution of the two filters are illustrated in FIGS. 6 and 7. FIGS. 6 and 7 show that the resulting filter after convolution exhibit the properties discussed above. In particular, FIG. 6 illustrates an impulse response of IF and AAF. FIG. 7 illustrates a convolution of IF and AAF.

According to an embodiment of the present invention, the largest magnitude element of h may be replaced with its sign. Also, the rest of the elements may be set to zero. Replacing the largest element with its sign may involve the scaling of h where such scaling may be absorbed in μ. Accordingly, there may be little or no approximation involved. After such scaling, the remaining elements having a magnitude less than one may be approximated to zero. With this approximation the coefficient vector h becomes a vector of zeros except one non-zero element (±1). Without loss of generality, the largest magnitude element of h may be assumed to be positive. The matrix-vector product may be reduced to a delayed version of the input vector, e.g.,

$${X}_{n}^{T} \hat{h} = [ \begin{matrix}x ( n - d ) \\ x ( n - d - 1 ) \\ ⋮ \\ x ( n - d - N + 1 )\end{matrix} ] ,$$

where ĥ is the approximate h and d is the index of the largest element of h.

Using this approximation, the LMS update may simplify to,

wₙ₊₁=wₙ−μe(n)x_{n-d},

where xₙ is the data vector defined before as

xₙ=[x(n), x(n−1), x(n−2), . . . x(n−N+1)]^{T}.

Hence, the simplified LMS update for RCDR-EC is similar to the normal LMS update except for the delay. In other words, the computational complexity of the simplified LMS for RCDR-EC of the present invention is similar to that of usual LMS.

Since both IF and AAF are part of the system design, the approximation does not restrict the use of the simplified LMS. Thus, the IF and AAF may be designed such that the resulting combined filter has at least a single dominant coefficient. Factors that may severely degrade the convergence and performance of LMS may include multiple dominant peaks in the combined filter response and inexact setting of the delay d.

The USB-O 522 with the zero filling structure may be combined with the IF 526 and efficiently implemented using a poly-phase structure, for example. The same may apply for the DSB 534 and AAF 532.

Differences between conventional echo canceller and RCDR-EC of the present invention may include various factors, such as structural differences, filter lengths, computation for LMS training, stead-state computational complexities and noise floor levels, for example.

As for structural differences, a conventional echo canceller may include an up sampling block followed by the adaptive FIR ECF that operates at the higher receive rate Rᵣₓ. In the RCDR-EC approach of the present invention, an adaptive FIR ECF may operate at the lower transmit rate Rₜₓ. In addition, a USB and a IF may be used to generate the echo samples at the receive rate and a DSB and an AAF may be used to calculate the error signal at the transmit rate.

As for filter lengths, to capture the same (or similar) fixed amount of time span (e.g., echo tail), the RCDR-EC of the present invention may include N filter taps as compared to the MN taps required by the conventional echo canceller approach. However, in addition to the ECF, RCDR-EC may implement at least two more filters, e.g., IF and AAF, for example. In general, the ECF is longer than the combined length of IF and AAF and hence, there is a significant reduction in number of filter taps. For example, for a typical value of N=256 and M=8, the conventional filter may require approximately 2048 taps. On the other hand, even with two 64 taps IF and AAF filters, the number of taps for RCDR-EC of the present invention is approximately 384, substantially less than that required in other systems.

As for LMS training computation, the computational complexity may be similar for the conventional LMS and simplified LMS for RCDR-EC of the present invention. For example, as the conventional ECF may be M times longer than that of the RCDR-EC of the present invention, the number of multiplications required for LMS update may be M times higher for a conventional echo canceller. Due to the reduction in the filter taps, even the exact LMS for RCDR-EC may have M/2 times lower complexity then the conventional approach.

As for steady-state computational complexity, in steady-state using efficient poly-phase implementation, for example, the total number of multiplications per second associated with RCDR-EC of the present invention may be represented by

(N+N_{f}+N_{g})Rₜₓ.

In contrast, even with efficient poly-phase implementation, the number of multiplications per second required by the conventional echo canceller is

NRᵣₓ,

In a typical implementation, the total filter length of IF and AAF is less than the filter length of ECF, e.g., N_{f}+N_{g}<N. As a result, RCDR-EC of the present invention may reduce the steady-state computation by at least a factor M.

As for noise floor level and overall performance, in a RCDR-EC system, the AAF filters out signals above a transmit band before generating the error signal e(n). Thus, the error signal reduces the contribution from the wide band receive signal which acts as noise for echo cancellers. In a conventional echo canceller, most or all the out of band receive signal works to contribute to the error signal. According to the present invention, this reduced noise floor for RCDR-EC results in reduced convergence time and improved overall performance of LMS. Other comparisons as well as advantages may be recognized by the present invention and variations thereof.

According to another embodiment of the present invention, a weighted error echo canceller for transceivers with unequal bandwidths is provided. The present invention enables an adaptive echo cancellation filter to perform at a lower sample rate.

Echo cancellers (EC) may be commonly used in full duplex communication systems to suppress the echo of the transmit signal entering the receive path. When the transmit and receive path have different bandwidths (hence, different sample rates), the echo canceller may need to bridge the rate difference. With conventional designs, the echo canceller filter operates at the higher sample rate. According to the present invention, an efficient echo cancellation scheme, referred to as Weighted Vector Error Echo Canceller (WEVE-EC) is proposed for various applications, such as applications where the receive path has a higher sampling rate. The WEVE-EC architecture may be implemented along with an adaptive algorithm, which may be based on Least Mean Square (LMS) update rules. Various other adaptive algorithms may be used to train the WEVE-EC of the present invention.

According to an embodiment of the present invention, an error vector, rather than a scalar error signal, may be implemented for updating the echo canceller. In a conventional approach, essentially all the sampling phases of the error signal are treated as consecutive time samples of a scalar signal at the receive rate. In the proposed structure of the present invention, most or all the sampling phases of the error signal may be stacked in a vector and treated as a vector sampled at the transmit rate.

An Error Weighting Multi-input-multi-output Filter (EWMF) of the present invention provides a flexible weighting scheme on most or all the sampling phases of the error signal. The Multi-Input Multi-Output (MIMO) filter structure is more general than the conventional Linear Time-Invariant (LTI) Finite Impulse Response (FIR) filters. In particular, the LTI FIR structure may be considered a special case of the proposed EWMF. Hence, the proposed structure of the present invention provides greater variety in selecting a training method for echo cancellers.

According to another embodiment of the present invention, the combination of an adaptive filter and an interpolation filter enables the echo canceller to operate at the lower transmit sample rate. This is in contrast to the conventional echo canceller approach where the echo canceller operates at the higher receive sampling rate. In addition, training and updating functionality of the echo canceller may be conducted at the same (or similar) low sample rate.

The architecture of the present invention reduces the number of filter coefficients without loss of performance. As a result, hardware requirement and computational complexities are significantly reduced and an increase in convergence speed of training algorithms may be achieved. Other advantages may be observed from the various embodiments of the present invention.

The proposed architecture may be suitable for steady-state tracking of the echo-canceller. The proposed architecture may also be easily modified for other situations, such as the reverse situation where the receive bandwidth is smaller than the transmit bandwidth.

The present invention provides an effective echo cancellation method that takes advantage of the situation where the transmit signal, and thus the echo signal generated from it, has a smaller bandwidth than that of the receive signal. The architecture of the present invention may include various components and function blocks, such as an Adaptive Echo Cancellation Filter (AECF) 810 which may operate at the lower transmit sample rate, an Interpolation Filter Bank (IFB) 820, and an Error Weighting MIMO Filter (EWMF) 830. Other functions may be implemented in the system of the present invention.

A corresponding LMS algorithm of the present invention provides training, tracking and/or other purposes. A filter bank design provides an efficient implementation for enabling some or all functional blocks to operate at the lower sample rate. Compared with the conventional echo cancellation filter which operates at the higher sample rate, the structure of the present invention offers improved performance, while significantly reducing the required number of taps, the sample rate, as well as yielding improved training behavior and less power consumption. Moreover, the proposed algorithm of the present invention also yields better convergence and stability properties during training and other phases.

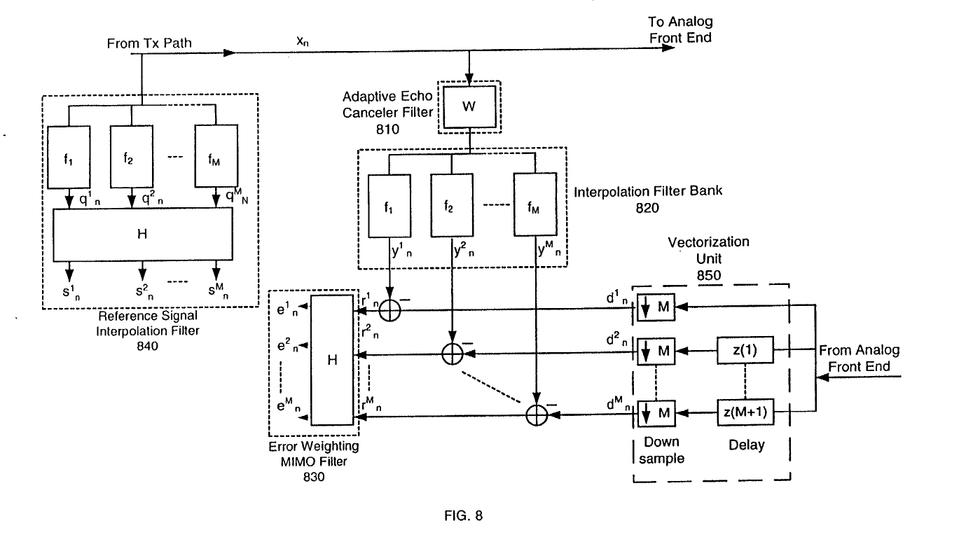

FIG. 8 illustrates a basic signal flow and the functional blocks of the WEVE-EC, according to an embodiment of the present invention. The Weighted Vector Error Echo Canceller (WEVE-EC) of the present invention may include various functional blocks, such as an Adaptive Echo Canceller Filter (AECF) 810; an Interpolation Filter Block (WFB) 820; an Error Weighting Multi-input-multi-output filter (EWMF) 830; a Reference Signal Interpolation Filter (RSIF) 840; and a Vectorization Unit (VU) 850. Other functional blocks may also be implemented, in accordance with the present invention.

The AECF 810 may include a FIR filter with Nw coefficients and an adaptive component of the WEVE-EC. The AECF 810 may operate at the lower transmit sample rate. The N_{w} coefficients of the AECF may be stacked into a vector w, where

w [w₀, w₁, . . . w_{Nw-1}]^{T}.

The coefficient vector w may be adapted during a training period and may be updated during the steady state. The AECF 810 may receive the transmit signal xₙ and generate a copy of the echo signal that is fed to the IFB 820.

The IFB 820 {f₁, . . . , f_{M}} may include a fixed filter bank for generating M branches of signals from the output of the AECF 810 to match a receive signal vector. The branches of signals may be organized into the vector yₙ≡[yₙ¹, . . . , yₙ^{M}]^{T} at each time instance or other time interval. For example, an integer M may be used where the architecture of the present invention may be easily modified with a scheme, such as a mixed upsample-downsample scheme, to accommodate various rational values of M. The output of the WFB 820 may include a vector signal yⁱⱼ which may be obtained by filtering the output of the AECF 810. This signal may be used to generate the residual echo rₙ.

The weighted error vector represents the training error of the adaptive echo canceller filter. The EWMF 830H allows a flexible weighting on the error vectors and thus offers a vast set of options for advanced training of the WEVE-EC of the present invention.

The RSEF 840 may include a fixed filter for generating a reference signal for training and/or other purposes. The filtering operation may involve a combination of the IFB 820 and the EWMF 830, for example.

The transmit signal xₙ may occupy a different (e.g., smaller) bandwidth than that of the receive signal. The filtered transmit signal qⁱⱼ may be obtained by filtering the transmit signal xₙ. The signal xₙ may then be used to generate the reference signal sⁱⱼ.

The reference signal sⁱⱼ may be obtained by filtering qⁱⱼ. The reference signal may be used for the LMS algorithm during the training of the AECF 810 with coefficient vector w.

The receive signal vector dₙ may be represented as

dₙ=[d¹ₙ, . . . , dₙ^{M}]^{T}.

This receive signal vector may be obtained by stacking the M sampling phases of the receive signal into a M length vector. The receive path may provide a sample rate M times higher than the transmit path. Hence, the vectorized receive signal dₙ has a sampling rate equal (or similar) to the transmit sampling rate.

The VU 850 may include sub blocks, such as Delay Units z(k) and Down Sampling blocks. Other sub blocks may also be incorporated by VU 850. The Delay Units sub block as designated by z(k) may delay a signal by K samples. The Down Sampling blocks as designated by M and a down arrow may be used to drop M−1 intermediate samples from the input signal. In other words, Down Sampling block decimates the input samples by a factor M.

The residual echo vector rₙ=dₙ−yₙ may be obtained by subtracting the output of the IFB 820 from the receive signal. During the training period, the residual echo vector rₙ may be used to generate the weighted error vector eₙ for the LMS update or other purpose. The weighted error vector eₙ may include the filtered residual echo vectors and may be used for training purposes, e.g., to train the AECF 810. Once the WAVE-EC is properly trained, eₙ may contain a small portion of the echo signal.

In the steady state, operational function blocks may be limited to the AECF 810, the IFB 820, and the VU 850. The RSIF 840 and the EWMF 830 may be implemented for training/tracking purpose. The signals for steady state operation may include the echo-canceller output yₙ^{k} and the echo cancelled signal rₙ^{k}. The signals sₖ and eₖ may be generated for the adaptive LMS.

Various echo canceller parameters for the architecture of the present invention as well as the LMS algorithm may be implemented as described in detail below.

Integer M may include the ratio of the receive sample rate to the transmit sample rate. M>1 implies that the transmit sample rate is lower than the receive sample rate. According to the present invention, the IFB 820 may be used on the transmit signal and a branching operation on the receive signal to bridge the transmit path and the receive path.

Adaptive Echo Canceller Filter 810 length N_{w} may represent the number of taps in filter 810. As the architecture of the present invention may operate at a lower sample rate, the length is substantially lower than that of an echo cancellation filter operating at a higher sample rate.

EWMF coefficients may be grouped into a matrix, such as {h_{m,n}; m=1, . . . , M, n=1, . . . , N_{H}}. The choice of the coefficients may depend on the nature of the transmit signal, receive signal, and/or the echo signal, as well as, the training algorithm used to train the echo canceller. Other factors may also be involved in the choice of coefficients.

The dimension of the EWMF matrix may be represented as M×N_{H}. For LMS algorithms, N_{H} may be a multiple of M, e.g., K=N_{H}/M is an integer. K may represent the number of residual echo vectors that are used to generate the weighted error vector. A larger EWMF matrix permits a more flexible weighting scheme on the error signal at the cost of higher complexity.

Interpolation Filter Bank (WFB) coefficients may be represented by {fₙ^{(k)};k=1, . . . , M, n=0, . . . , N_{f}−1}: A dedicated filter of length Nf may exist for each of the M signal branches. These coefficients may be chosen such that a desired interpolation filtering performance is achieved with a given filter length.

Interpolation Filter Bank length may be represented by N_{f}. The length may be decided by a desired performance of the up sampling block, the computational cost and/or other factors. The performance as well as the complexity may increase with the length of the filter.

LMS update step size sequence may be represented by μₙ. Generally, the larger the step size, the faster the training will converge. However, there may be a limit on the magnitude of the step size. For example, a large enough value may cause the training algorithm to diverge. On the other hand, the smaller the value of μₙ, the smaller the error floor. For example, the step size sequence may be chosen as constant or as a decreasing set of numbers such that the algorithm quickly achieves convergence with large step sizes at the early stages of the training procedure and obtains low error floor with smaller step sizes later in the training procedure. This is commonly known as a gear shifting method.

The training procedure of the present invention may involve adapting the coefficients of the echo canceller filter based on up-sampled reference sequences and/or weighted error signal. Other factors may be considered. The adaptive echo canceller may be matched to the echo path such that a significant component of the echo component in the receive signal may be cancelled. The effectiveness of the echo cancellation may be measured by the energy of the weighted error signal. The tracking procedure may use the same (similar or related) update mechanism as that of the training procedure or a variation thereof.

The training method is not limited to the LMS algorithm as discussed above, but other algorithms may be used instead of LMS, in accordance with the present invention. The scalar form of an LMS update rule may be described as follows:

wₙ₊₁=wₙ+μₙeₙ

where wₙ is the adaptive entity for the LMS algorithm, eₙ is an error signal, n is the time index, and μₙ is the LMS step size. The update rule for the proposed LMS algorithm is shown below in step 918. Compared with the scalar form, the proposed update rule of the present invention provides a more flexible weighting scheme for the error signal.

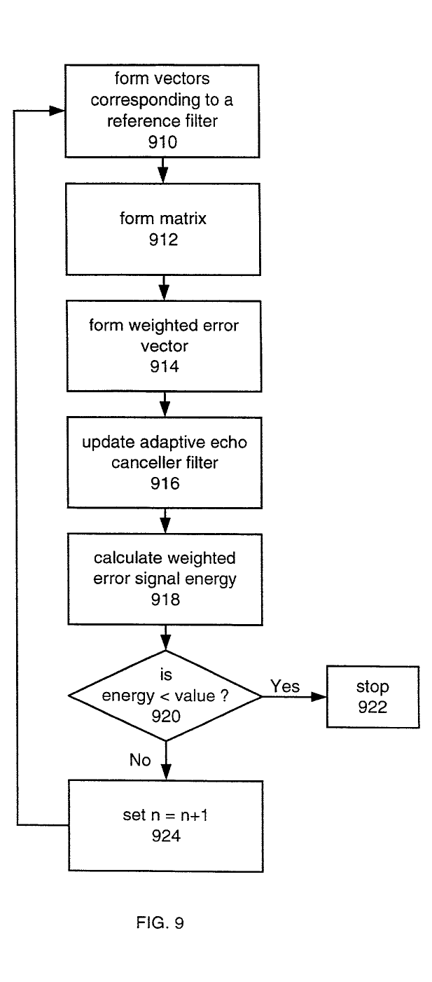

In the proposed LMS algorithm, each update may involve the steps of FIG. 9. At step 910, a vector corresponding to a reference filter may be formed. At step 912, a matrix may be formed. At step 914, a weighted error vector may be formed. At step 916, an adaptive echo canceller filter may be updated. At step 918, the weighted error signal energy may be calculated. The steps of FIG. 9 will be described in detail below.

At step 910, vectors sₙ¹, . . . , sₙ^{M}, corresponding to reference filter may be formed where

$${s}_{n}^{k} = {[ \begin{matrix}{s}_{n}^{k} & {s}_{n - 1}^{k} & ↑ & {s}_{n - Nw + 1}^{k}\end{matrix} ]}^{T} .$$

At step 912, the matrix may be formed as follows:

$${S}_{n} = [ {s}_{n}^{1} ↑ {s}_{n}^{M} ] .$$

At step 914, weighted error vector may be formed as follows:

eₙ=[eₙ¹ eₙ² ↑ eₙ^{M}]^{T}.

At step 916, the adaptive echo canceller filter may be updated as follows:

wₙ₊₁=wₙ+μₙSₙeₙ.

At step 918, the weighted error signal energy eₙ^{T}eₙ may be calculated. At step 920, it may be determined whether the energy is less than a predetermined value. If so, the process may be terminated at step 922. If the energy level is equal to or above a predetermined value, then n=n+1 and a feedback loop to step 910 may be established.

The present invention also provides advantages with respect to computational complexity. For example, it may take N_{w}+MN_{f}+MN_{H} multiplications to generate the weighted error vector eₙ, MN_{f}+MN_{H} multiplications to form the matrix Sₙ, and M²N_{w} multiplications to execute the update equation for each update of the AECF. In total, (1+M²)N_{w}+2M(N_{f}+N_{H}) multiplications may be required for each update of the AECF.

Additional details of the LMS algorithm of the present invention will now be described. The output of the echo canceller interpolation filter bank (e.g., IFB 820)

$${y}_{n} = {[ {y}_{n}^{1} , ↑ , {y}_{n}^{M} ]}^{T} ,$$

may be written as

yₙ=FXₙwₙ

where F represents the echo canceller Interpolation Filter Bank, e.g.,

$$F = [ \begin{matrix}{f}_{0}^{( 1 )} & {f}_{1}^{( 1 )} & ⋯ & {f}_{Nf - 1}^{( 1 )} \\ {f}_{0}^{( 2 )} & {f}_{1}^{( 2 )} & ⋯ & {f}_{Nf - 1}^{( 2 )} \\ ⋮ & ⋮ & ⋰ & ⋮ \\ {f}_{0}^{( M )} & {f}_{1}^{( M )} & ⋯ & {f}_{Nf - 1}^{( M )}\end{matrix} ] ,$$

and

$${X}_{n} [ \begin{matrix}{x}_{n} & ⋯ & {x}_{n - Nw + 1} \\ {x}_{n - 1} & ⋯ & {x}_{n - Nw} \\ ⋮ & ⋰ & ⋮ \\ {x}_{n - Nf + 1} & ⋯ & {x}_{n - Nf - Nw + 2}\end{matrix} ] ,$$

is the transmit signal matrix.

In one example, the filter bank F may implement a zero-insertion plus low-pass filtering operation. In such cases, F may be written as

$$F = [ \begin{matrix}{f}_{0} & {f}_{M} & ⋯ & {f}_{( Nf - 1 ) M} \\ {f}_{1} & {f}_{M + 1} & ⋯ & {f}_{( Nf - 1 ) M + 1} \\ ⋮ & ⋮ & ⋰ & ⋮ \\ {f}_{M - 1} & {f}_{2 M - 1} & ⋯ & {f}_{NfM - 1}\end{matrix} ] ,$$

where [f₀, . . . , f_{NfM-1}]^{T} may be a N_{f}M-length low-pass filter.

As the receive signal may occupy a larger bandwidth than that of the transmit signal, the residual echo vector may have a significant out-of-band noise. This out-of-band noise has detrimental effect on the adaptation process and should be removed. According to an embodiment of the present invention, the out-of-band noise may be removed or minimized by passing the residual echo vector through the EWMF, or other filter. As discussed above, the residual echo signal may be represented by

rₙ=dₙ−yₙ.

Using the residual echo signal, the weighted error vector may be written as

$${e}_{n} ≡ [ \begin{matrix}{e}_{n}^{1} \\ ⋮ \\ {e}_{n}^{M}\end{matrix} ] = H \cdot [ \begin{matrix}{r}_{n} \\ ⋮ \\ {r}_{n - K + 1}\end{matrix} ] .$$

In the formulation, K=N_{H}/M residual echo vectors may be involved in the filtering operation to generate a filtered error vector. By using the matrix

$$H = [ \begin{matrix}{h}_{1 , 1} & {h}_{1 , 2} & ⋯ & {h}_{1 , {N}_{H}} \\ {h}_{2 , 1} & {h}_{2 , 2} & ⋯ & {h}_{2 , {N}_{H}} \\ ⋮ & ⋮ & ⋰ & ⋮ \\ {h}_{M , 1} & {h}_{m , 2} & ⋯ & {h}_{M , {N}_{H}}\end{matrix} ] ,$$

to represent the weighting operation, the possibility of using different filters for each sampling phase is preserved. For the special case where a single K tap FIR filter is used for all sampling phase, the H may become a Toeplitz matrix with the first row

$$\{ {h}_{1} , \underbrace{0 , … 0}_{M - 1 zeros} , {h}_{2} , \underbrace{0 , … , 0}_{M - 1 zeros} , {h}_{3} , … {h}_{K - 1} \underbrace{0 , … , 0}_{M - 1 zeros} , {h}_{K} \} ,$$

where the K non zeros elements {h₁, . . . , h_{K}} may be defined as the FIR filter coefficients. A Toeplitz matrix generally refers to a matrix whose entries are constant along each diagonal.

After defining the necessary signals, the corresponding Least Mean Square (LMS) algorithm for the coefficients of the echo cancellation filter may be derived in accordance with the present invention. For example, the instant gradient for the LMS training algorithm may be obtained by taking the derivative of eₙ^{T}eₙ with respect to w. The update rule may then be represented as:

$${w}_{n + 1} = {w}_{n} - \frac{{μ}_{n}}{2} \frac{\partial {e}_{n}^{T} {e}_{n}}{\partial {w}_{n}}$$

=wₙ+μₙ[Xₙ^{T}F^{T}|↑|X^{T}_{n-K+1}F^{T}]·H^{T}·eₙ.

The matrix multiplication in the update rule may represent the operations performed in the reference signal interpolation filter (e.g., 840) in FIG. 8.

[Xₙ^{T}F^{T}| . . . |X^{T}_{n-K+1}F^{T}]·H^{T}

$$[ {X}_{n}^{T} {F}^{T} \vert … \vert {X}_{n - K + 1}^{T} {F}^{T} ] \cdot {H}^{T} = [ \begin{matrix}{q}_{n}^{1} & ⋯ & {q}_{n}^{M} & {q}_{n - 1}^{1} & ⋯ & {q}_{n - 1}^{M} & ⋯ & {q}_{n - K + 1}^{1} & ⋯ & {q}_{n - K + 1}^{M} \\ {q}_{n - 1}^{1} & ⋯ & {q}_{n - 1}^{M} & {q}_{n - 2}^{1} & ⋯ & {q}_{n - 2}^{M} & ⋯ & & & \\ & ⋮ & & & & & & & ⋮ & \\ {q}_{n - Nw + 1}^{1} & ⋯ & {q}_{n - Nw + 1}^{M} & & ⋯ & & & {q}_{n - K - Nw + 2}^{1} & ⋯ & {q}_{n - K - Nw + 2}^{M}\end{matrix} ] \cdot {H}^{T} = [ \begin{matrix}{s}_{n}^{1} & ⋯ & {s}_{n}^{M} \\ {s}_{n - 1}^{1} & ⋯ & {s}_{n - 1}^{M} \\ & ⋮ & \\ {s}_{n - Nw + 1}^{1} & ⋯ & {s}_{n - Nw + 1}^{M}\end{matrix} ] ≡ {S}_{n}$$

where the filtered output sⱼⁱ may be arranged into a matrix. The final form of the update rule may be represented as

wₙ₊₁=wₙ+μₙSₙeₙ.

According to another embodiment of the present invention, a minimum mean square error linearly constrained fast algorithm for adaptive training of a Time Domain Equalizer (MLC-TEQ) is provided. A fast adaptive algorithm of the present invention may be used to obtain Finite Impulse Response (FIR) filter coefficients for Time domain Equalizer (TEQ) used in Discrete Multitone (DMT) based applications, such as ADSL, for example. The TEQ coefficients obtained by the algorithm of the present invention shortens the overall effective discrete time channel impulse response length within a given target length (e.g., symbol prefix length for DMT application). Advantages of the proposed data aided adaptive algorithm may include providing the TEQ filter coefficients with near-optimal performance; having low computational requirements, having fast convergence, and exhibiting attractive stability properties. Other advantages may also be realized by the present invention and variations thereof.

Other features of the algorithm of the present invention may include implementing a Target Impulse Response (TIR) vector, e.g., the combined response of the transmission channel and TEQ filter, as a search vector, e.g., the vector that needs to be calculated.

The algorithm of the present invention may constrain a selected element of the TIR vector to be approximately equal to a constant where the selected element may be any element of the TIR vector. The error may be computed by using the difference between the TEQ output and TIR filter output. TEQ filter coefficients may be adaptively computed by minimizing the Mean Square Error (MSE) criterion. TEQ filter obtained through the algorithm of the present invention may provide minimal energy Inter Symbol Interference (ISI) and Inter Channel Interference (ICI).

The computation requirement of the algorithm of the present invention may be linear in equalizer length, e.g., the number of filter taps of the equalizer. As a result, the algorithm is suitable for practical implementation in various applications. The algorithm of the present invention may adaptively calculate an equalization delay using the training and received sequences thereby providing efficient use of FIR TEQ filter coefficients. The algorithm of the present invention may incorporate input data conditioning through use of dummy signals thereby providing enhanced stability and improved convergence.

The present invention provides a fast, stable and high performance adaptive algorithm for computation of near-optimal FIR TEQ coefficients. The resulting TEQ filter shortens the overall channel response such that residual energy of the overall channel outside the target length is minimized. In applications, such as DMT, TEQ filters obtained through the algorithm of the present invention provides minimum energy Inter Symbol Interference (ISI) and Inter Channel (or Carrier) Interference (ICI) and as a result yields a higher bit rate. Other advantages may also be recognized.

In Discrete Multitone (DMT) systems, it may be desirable for the discrete time channel spread to be less than a prefix length to avoid ISI and ICI. In some applications, the spread of the channel may be greater than the prefix length. Hence, preprocessing of data may be implemented to shorten the effective channel seen by the DMT receiver. An approach, e.g., Time domain Equalization (TEQ), may be implemented to apply (sample or fractionally spaced) linear filtering to the sampled receive data to shorten the effective channel spread. The present invention provides an approach to designing sample spaced and fractionally spaced (e.g., with factor 2 or other factor) Finite Impulse Response (FIR) TEQ filters.

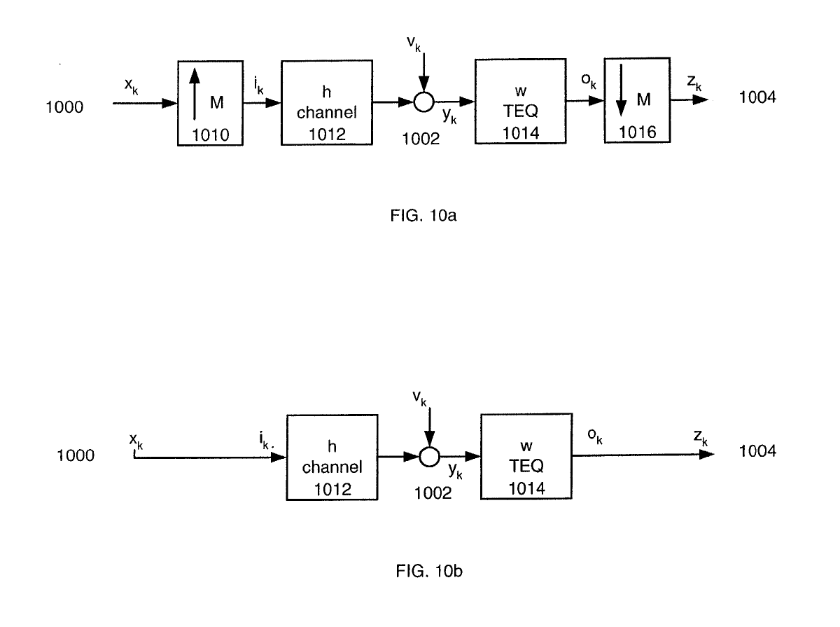

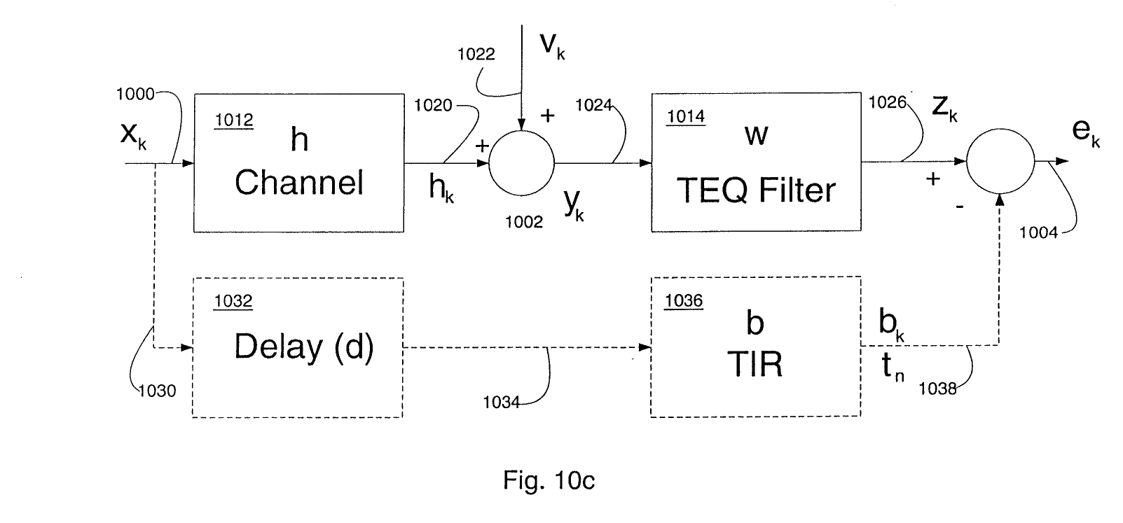

FIG. 10a outlines a basic setup for a TEQ system, according to an embodiment of the present invention. Here, xₖ represents the k-th sample of the transmitted signal with variance \mathring{9}²ₓ. Block 1010 with up-arrow and M corresponds to an up-sampling function with factor M, which may involve inserting M−1 zeros between the samples of xₖ. For example, for M=2 case, iₖ sequence may be given by

←, 0, x₋₂, 0, x₋₁, 0, x₀, 0, x₁, 0, x₂, 0, x₃, 0, ←

For example, M=1 may refer to a sample spaced TEQ, as represented in FIG. 10b, and M=2 may refer to a fractionally spaced TEQ.

The combined effects of the transmit filter shaping, the receiver filter, and the distortion caused by the transmission channel may be modeled by a Linear Time Invariant (LTI) system, as illustrated by 1012, with impulse response denoted by hₖ. The combined effects of the receiver noise and the interferences may be modeled by the additive disturbance vₖ.

In FIG. 10a, block 1014 represents a TEQ filter having N_{TEQ} filter coefficients. N_{TEQ} TEQ coefficients may be denoted by {w₁, w₂, ←, w_{NTEQ}} and TEQ coefficient vector may be denoted by w, e.g.,

w=[w₁←w_{NTEQ}]^{T}

An output of the TEQ filter 1014 may be down-sampled where the down sampling process is represented by a block 1016 with down-arrow and M. The down-sampling operation may involve selecting 1 out of M samples of oₖ. For example, for M=2 case, zₖ sequence may include

←o₋₂, o₀, o₂, o₄, ←

The time domain equalization may convert the channel impulse response hₖ into an impulse response with N_{T} nonzero consecutive entries. Therefore, if the nonzero entries of the resulting channel are modeled with the sequence {bₖ; kχ{0←N_{T}−1}}, the target channel may be modeled as

$${t}_{n} = \{ \begin{matrix}{b}_{n - d} & d \leq n \leq d + {N}_{T} - 1 \\ 0 & otherwise ,\end{matrix}$$

where d is the effective delay corresponding to the starting location of the non-zero segment of the impulse response.

In DMT based DSL systems, such as G.dmt and G.lite, standard generally dedicates certain training sequences for the computation of TEQ coefficients. These training sequences may be periodic DMT symbols without prefix where the period is one symbol long, for example. According to one example, {pₙ, nχ{0, ←, N_{R}−1}} may represent the DMT symbol of length N_{R}, where the transmitted training sequence rₙ represents the repeated version of pₙ, e.g.,

rₙ=pₘ and m=mod(n,N_{R})

where mod(n,N_{R}) is the remainder of n/N_{R} and hence, m is an integer between 0 and N_{R}−1.

Therefore, rₙ may represent a periodic extension of the sequence pₙ, e.g., rₙ may be obtained through periodic repetition of pₙ where the period is N_{R}. The periodic extension may be expressed as

←,p_{NR-2},p_{NR-1},p₀,p₁,p₂,←,p_{NR-1},p₀,p₁,←

An adaptive TEQ problem may involve developing an algorithm that processes training signal rₙ and corresponding received signal yₙ to obtain TEQ filter coefficients without any a priori knowledge of channel and noise statistics.

For DMT applications, an optimal approach may involve choosing {wₖ} such that the number of bits loaded per symbol may be maximized. However, this approach may be difficult to implement and impractical for adaptive implementations. Other alternative schemes either have high computational complexity and are therefore not suitable for adaptive implementations or have lower complexity but low performance and instability in the convergence. The present invention provides an adaptive approach that yields enhanced (or near-optimal) performance.

MLC-FAST-TEQ algorithm of the present invention uses training data sequence {rₙ}, and the corresponding received data sequence {yₙ}. Exemplary special cases for the algorithm may include a Sample Spaced Case where M=1 and a Fractionally Spaced Case with factor 2 where M=2. In the Fractionally Spaced Case, {yₑₙ} and {yₒₙ} may represent even and odd phases of the received sequence respectively, e.g.,

yₑₙ=y₂ₙ

yₒₙ=y_{2n+1,}

where yₙ is the over-sampled received sequence.

In this section, various algorithm parameters, which may include predetermined constants independent of the data, may be used in the algorithm of the present invention. Their values may be adjusted to achieve different levels of performance and stability as well as other results.

The algorithm may assume certain conditions about the amount of training sequence data required, e.g., the length of the training sequence Nₜᵣ. For example, the training sequence may involve consecutive samples of the received signal {yₙ; nχ{0, . . . , Nₜᵣ−1}} for the sample spaced case. In another example, the training sequence may involve consecutive samples of the sequences {yₑₙ; nχ{0, . . . , Nₜᵣ−1}} and {yₒₙ; nχ{0, . . . , Nₜᵣ−1}} for the fractionally spaced case.

Parameters used in the algorithm of the present invention include: N_{T} which represents target channel length; N_{TEQ} which represents TEQ filter length; N_{R} which represents symbol length; L which represents fixed tap location where Lχ{0, . . . , N_{T}−1}; N_{S} which represents TEQ algorithm search vector size N_{S}=N_{T}+N_{TEQ}; \mathring{2} which represents least square cost function forgetting factor; N_{D} which represents maximum tone number for the dummy signal and N_{χ} which represents number of update variables where

$${N}_{χ} = \{ \begin{matrix}3 & Sampled SpacedCase \\ 4 & FractionallySpacedCaseWithFactor2 .\end{matrix}$$

Other parameters may include {Cₖ; kχ{0, ←, N_{D}−1}} which represents frequency domain dummy signal values. There are N_{D} such complex values, e.g., Cₖ may be complex numbers. Other parameters may include { [symbol] ₙ} which represents time domain dummy signal, which may be determined by the frequency domain dummy signal values. The following equation shows the relation:

$${801}^{ZCode} = {C}_{0} + {\sum }_{k = 1}^{{N}_{D} - 1} 2 Real part of \{ {C}_{k} {ⅇ}^{j2 {6}^{◯} kn / {N}_{R}} \} n χ \{ 0 , ← , {N}_{R} - 1 \} .$$

where the term Real part of stands for the real part of a complex number. The time domain dummy signal may be defined as the repeated version of [symbol] ₙ, e.g., { [symbol] ₙ= [symbol] ₘ}, where m=mod(n, N_{R}). In other words, [symbol] ₙ may represent the periodic extension of the signal [symbol] ₙ.

Other parameters may include S which represents the scaling of the received dummy signal; [symbol] which represents Internal dynamic range arrangement parameter; and [symbol] which represents a priori variance constant used for the initialization of the matrix F.

The MLC-FAST-TEQ algorithm of the present invention includes at least two steps, which may include the adaptive computation of the equalization delay parameter d and the adaptive computation of the TEQ filter coefficients based on the delay d calculated in the first step.

An estimate of cross-correlation function {q(k); kχ{0, ←, M×N_{R}−1}} may be computed as

$$q ( k ) = {\sum }_{l = 0}^{{N}_{av} - 1} {\sum }_{n = 0}^{{N}_{R} - 1} {r}_{n} y ( {M}_{n} + k + {lN}_{R} ) \}$$

where NₐᵥMN_{R}<Nₜᵣ.

Then \mathring{1} may be defined as the argument maximizing the absolute value of the cross-correlation function:

\mathring{1}=argmaxₖ|q(k)|

Therefore, \mathring{1} represents the peak point location for the absolute cross-correlation function.

An equalization delay d may be selected as a function of \mathring{1}. An appropriate choice of d may be given by:

d=1/M{\mathring{1}+N_{TEQ}/2}.

In other words,

$$d = \{ \begin{matrix}κ + \frac{{N}_{TEQ}}{2} & Sampled SpacedCase \\ \frac{κ}{2} + \frac{{N}_{TEQ}}{4} & FractionallySpacedCase\end{matrix}$$

Adaptive computation of TEQ coefficients for a sample spaced case includes algorithm variables such as the following:

[symbol] : Column Vector (Size N_{χ}×1.);

\mathring{5}: Column Vector (Size N_{χ}×1.);

[symbol] : Column Vector (Size N_{χ}×1.);

\mathring{8}: Column Vector (Size N_{χ}×1.);

[symbol] : Column Vector (Size N_{χ}×1.);

A: Matrix (Size N_{χ}×N_{S}), initialized to all zeros;

D: Matrix (Size N_{χ}×N_{S}), initialized to all zeros;

X: Column Vector (Size N_{S}×1), initialized to all zeros;

k: Column Vector (Size N_{S}×1), initialized to all zeros;

F: Matrix (Size N_{χ}×N_{χ}), initialized to [symbol] I_{Nχ}, where I_{Nχ} stands for identity matrix of size N_{χ}×N_{χ};

t: Column Vector (Size N_{χ}×1), initialized to all zeros;

b: Column Vector (Size N_{S}×1), initialized to all zeros;

m: Column Vector (Size N_{S}×1);

\mathring{3}: Column Vector (Size N_{χ}×1);

c: Column Vector (Size N_{S}×1), initialized to all zeros;

\hat{x}: Scalar;

e: Scalar; and

n: Scalar.

TEQ coefficient algorithm steps include the following:

$$\begin{matrix}step 1. & n = 0 , \\ step 2. & {802}^{ZCode} = [ \begin{matrix}{y}_{n} + S {ψ}_{n - d} \\ {r}_{n - d} + {ψ}_{n - d} \\ {r}_{n - d - L - 1} + {ψ}_{n - d - L - 1}\end{matrix} ] . \\ step 3. & {803}^{ZCode} = [ \begin{matrix}{X}_{{N}_{TEQ}} \\ {X}_{{N}_{TEQ} + L - 1} \\ {X}_{{N}_{TEQ} + {N}_{P}}\end{matrix} ] , \\ step 4. & {804}^{ZCode} = {802}^{ZCode} + AX , \\ step 5. & A = A - k {805}^{ZCode} , \\ step 6. & {806}^{ZCode} = {804}^{ZCode} ( 1 - {k}^{T} X ) , \\ step 7. & F = {807}^{ZCode} F , \\ step 8. & t = F ( \frac{∈}{\frac{1}{α} + {ϵ}^{T} F ∈} ) \\ step 9. & F = F - t ( {805}^{ZCode} F ) , \\ step 10. & t = {808}^{ZCode} F {804}^{ZCode} , \\ step 11. & b = k + At , \\ step 12. & m = [ \begin{matrix}{t}_{1} \\ {b}_{1. ( {N}_{TEQ} - 2 )} \\ {t}_{2} \\ {b}_{( {N}_{TEQ} + 1 ) ( {N}_{TEQ} + L - 2 )} \\ {t}_{3} \\ {b}_{( {N}_{TEQ} + L ) : ( {N}_{S} - 1 )}\end{matrix} ] , \\ step 13. & {809}^{ZCode} = [ \begin{matrix}{b}_{NTEQ} & {b}_{NTEQ + L - 1} & {b}_{Ns}\end{matrix} ] , \\ step 14. & X = [ \begin{matrix}{ξ}_{1} \\ {X}_{1 ( {N}_{TEQ} - 1 )} \\ {ξ}_{2} \\ {X}_{( {N}_{TEQ} + 1 ) : ( {N}_{TEQ} + L - 2 )} \\ {ξ}_{3} \\ {X}_{( {N}_{TEQ} + L ) \cdot ( {N}_{S} - 1 )}\end{matrix} ] , \\ step 15. & {822}^{ZCode} = {803}^{ZCode} + DX , \\ step 16. & k = ( \frac{m - D μ}{1 - {η}^{T} μ} ) \\ step 17. & D = D - k {823}^{ZCode} , \\ step 18. & \hat{x} = {c}^{T} X , \\ step 19. & e = {r}_{n - d - L - 1} + {810}^{ZCode} - \hat{x} , \\ step 20. & c = c + ke , \\ step 21. & n = n + 1 , \\ step 22. & if n < {N}_{tr} then go to step 2 , else stop .\end{matrix}$$

TEQ coefficients may be given by the first NTEQ taps of the vector c, e.g.,

w=c_{1:NTEQ}

Adaptive computation of TEQ coefficients for a fractionally spaced case with Factor 2 (e.g., M=2) may include variables that are identical (or similar) to that for the sampled spaced case, discussed above. The steps for the algorithm may include the following:

$$\begin{matrix}step 1. & n = 0 , \\ step 2. & {811}^{ZCode} = [ \begin{matrix}{y}_{en} + S {ψ}_{n - d} \\ {y}_{on} \\ {r}_{n - d} + {ψ}_{n - d} \\ {r}_{n - d - L - 1} + {ψ}_{n - d - L - 1}\end{matrix} ] , \\ step 3. & {812}^{ZCode} = [ \begin{matrix}{X}_{{N}_{TEQ} - 1} \\ {X}_{{N}_{TEQ}} \\ {X}_{{N}_{TEQ} + L - 1} \\ {X}_{{N}_{TEQ} + {N}_{P}}\end{matrix} ] , \\ step 4. & {813}^{ZCode} = {811}^{ZCode} + AX , \\ step 5. & A = A - k {814}^{ZCode} , \\ step 6. & {813}^{ZCode} = {815}^{ZCode} ( 1 - {k}^{T} X ) , \\ step 7. & F = {816}^{ZCode} F , \\ step 8. & t = F ( \frac{∈}{\frac{1}{α} + {ϵ}^{T} F ∈} ) \\ step 9. & F = F - t ( {814}^{ZCode} F ) , \\ step 10. & t = {817}^{ZCode} F {813}^{ZCode} , \\ step 11. & b = k + At , \\ step 12. & m = [ \begin{matrix}{t}_{1} \\ {t}_{2} \\ {b}_{1. ( {N}_{TEQ} - 2 )} \\ {t}_{3} \\ {b}_{( {N}_{TEQ} + 1 ) ( {N}_{TEQ} + L - 2 )} \\ {t}_{4} \\ {b}_{( {N}_{TEQ} + L ) \cdot ( {N}_{S} - 1 )}\end{matrix} ] , \\ step 13. & {818}^{ZCode} = [ \begin{matrix}{b}_{NTEQ} & {b}_{NTEQ + L - 1} & {b}_{Ns}\end{matrix} ] , \\ step 14. & X = [ \begin{matrix}{ξ}_{1} \\ {ξ}_{2} \\ {X}_{1 : ( {N}_{TEQ} - 2 )} \\ {ξ}_{3} \\ {X}_{( {N}_{TEQ} + 1 ) \cdot ( {N}_{TEQ} + L - 2 )} \\ {ξ}_{4} \\ {X}_{( {N}_{TEQ} + L ) : ( {N}_{S} - 1 )}\end{matrix} ] , \\ step 15. & {819}^{ZCode} = {812}^{ZCode} + DX , \\ step 16. & k = ( \frac{m - D μ}{1 - {η}^{T} μ} ) \\ step 17. & D = D - k {820}^{ZCode} , \\ step 18. & \hat{x} = {c}^{T} X , \\ step 19. & e = {r}_{n - d - L - 1} + {821}^{ZCode} - \hat{x} , \\ step 20. & c = c + ke , \\ step 21. & n = n + 1 , \\ step 22. & if n < {N}_{tr} then go to step 2 , else stop .\end{matrix}$$

TEQ coefficients are given by the first NTEQ taps of the vector c, e.g.

w=c_{1:NTEQ}

Further to the adaptive manner of obtaining FIR coefficients in a TEQ filter described above, we now turn to a method and system for shortening the channel impulse response in DMT systems wherein a model is employed to effectively represent a hypothetical delay transmit signal in conjunction with a desired shortened channel impulse response filter to arrive at near optimal TEQ coefficients. In contrast to the adaptive process described above, where the TEQ setup involved a fractionally spaced TEQ scenario in which up-sampling/down-sampling factor M=2, as shown in FIG. 10a, the TEQ filter solution described in this section is based on a sample spaced TEQ setup in which M=1, as shown in FIG. 10b.

In DMT systems, each received data symbol or packet is commonly prepended with a guard sequence called the cyclic prefix that is used to space the symbols so that the receiving system recognizes each individual packet of data. Each DMT symbol typically consists of N samples (where N is an arbitrary integer), while the cyclic prefix is a copy of the last v (where v is an integer less than N) samples of the DMT symbol. In order to prevent ISI, the value of v must be greater than or equal to the length of the channel impulse response, i.e, the channel length, commonly denoted by the variable h.

Upon receipt of the symbol by the receiving modem, the cyclic prefix is discarded, since it includes no information not otherwise included within the symbol. The symbol is further processed, and conventional methods of shortening the channel impulse response are applied. Because the cyclic prefix does not convey any new information about the transmitted signal, efficiency of the system decreases in proportion to N/(N+v). Therefore, in order to maximize system efficiency, either N should be large, or v should be small. However, as N increases, memory requirements in the communications system are also increased.

In DMT systems, it is further desirable that the discrete time channel spread is less than the prefix length so as to avoid ISI as well as ICI, which is the convolution of signals on overlapping carrier channels. In applied systems, the spread of the channel is typically significantly greater than the prefix length. Therefore, preprocessing of data is required to shorten the effective channel seen by the DMT receiver, thereby reducing the occurrence of ISI and ICI. The most common approach to this preprocessing function is to apply Time Domain Equalization (TEQ) to the sampled receive data to shorten the effective channel spread. TEQ refers to a process for filtering the incoming signal in such a way as to combine the data signals from various channels and reduce the cyclic prefix of the resulting signal to a uniform size that is as small as possible.

FIG. 10b illustrates the basic scenario involving the above described TEQ problem. In particular, xₖ (where k is an integer) 1000 denotes the transmitted signal that is propagated along a channel and ultimately received by a modem. The transmitted signal includes, for instance, v+1 input samples. The effects resulting from the transmission channel are modeled and represented by the h channel block 1012, where the resultant, hₖ, denotes the original “long” channel impulse response. k is a whole number from 1 to N_{C}, where N_{C} is the channel impulse response length of the channel h. The resultant signal hₖ is further distorted by additive disturbance vₖ (where k is a real number), which models the receiver noise and other signal interferences. This effect is represented, for purposes of illustration, by the combination of hₖ and vₖ at hypothetical adder 1002. The resultant is the combined, unfiltered signal yₖ that represents the signal as input at the receiver device, for instance a modem. The signal yₖ is received at the TEQ filter 1014 for preprocessing as described further below. The signal yₖ is the resultant vector of the current and previous received samples, N_{W}, and is passed through TEQ filter 1014, which operates to shorten the channel impulse response of yₖ and results in output signal vector zₖ 1004. The TEQ vector w^{T} to be applied to the signal yₖ may be calculated using TEQ filter coefficients {wₖ}, and vice-versa, and is combined with the signal yₖ to produce the filtered output signal zₖ 1004 having a shortened channel impulse response.

Initially, the transmitted signal, xₖ 1000, is assumed to be an uncorrelated and identically distributed wide sense stationary sequence having a zero mean and a squared variance of xₖ, σₓ². It should be understood that this assumption is not entirely accurate in that the existence of the cyclic prefix, which is the simple repetition of a portion of the transmitted samples, causes some degree of correlation among the samples. However, generally, the separation between the repeated samples is large enough to neglect the correlation due to the prefix.

Accordingly, the combined effects of the transmission filter, the receiver filter, and the distortion caused by the transmission channel are modeled by a linear time invariant system with the impulse response hₖ. As briefly described above, the receiver noise and other interferences are modeled by additive disturbance vₖ, which is assumed to be a wide sense stationary sequence having a zero mean and correlation coefficients represented by:

rᵥ(m)=E(vₖvₖ*+m)

where m is a real number and where rᵥ is the noise autocorrelation sequence.

In one manner, the TEQ filter vector w^{T} is calculated using a number (designated as N_{TEQ}) of Finite Impulse Response (FIR) TEQ filter coefficients {wₖ}, where the coefficients are defined as:

{wₖ; kε{1 . . . ^{N}_{TEQ}}}and

w=[w₁←w_{NTEQ}]^{T}

A goal of TEQ is to convert the channel impulse response hₖ into a target impulse response with effectively only a certain number of nonzero entries, designated as N_{T}. Therefore, if the nonzero entries of the resulting channel are modeled with the sequence bₖ, where k is a whole number from 0 to Nₚ−1, the target channel, tₙ, can be formulated as:

$${t}_{n} = \{ \begin{matrix}{b}_{n - d} & d \leq n \leq d + {N}_{T} - 1 \\ 0 & otherwise ,\end{matrix} \}$$

where d is the effective delay corresponding to the starting location of the non-zero segment of the impulse response.

For TEQ filtering in a DMT system, one optimal approach involves selecting {wₖ} such that the number of bits loaded per symbol, B, is maximized. This approach is equivalent to maximizing B as:

$$B ( w ) = {\sum }_{i ∈ T} {log}_{2} \{ 1 + \frac{{S}_{i} ( w )}{( {I}_{i} ( w ) + {N}_{i} ( w ) ) Γ} \}$$

where T is the set of transmit tones, Sᵢ(w) is the desired signal energy at tone i, Iᵢ(w) is the combined energy of ISI and ICI at tone i caused by the components of tₙ outside d≦n≦d+N_{T}−1, Nᵢ(w) is the noise energy at tone I, and Γ is the effective gap which is a function of the constellation, coding gain, and the margin requirement.

Unfortunately, the maximization of B with respect to w is a difficult, processor intensive computation, and is impractical for most real world, adaptive implementations. Therefore, some alternative near-optimal schemes have been developed. One such scheme includes maximizing the geometric Signal to Noise Ratio (SNR_{G}) as:

$${SNR}_{G} {=}^{Δ} {\prod }_{i ∈ T} \frac{{S}_{i} ( w )}{{I}_{i} ( w ) + {N}_{i} ( w )}$$

SNR_{G} can be defined as the product of SNRs at each transmitted tone within the symbol. However, this process is also computationally complex and, consequently, is also unsuitable for practical applications. Alternative, comparatively lower complexity approaches such as that described in U.S. Pat. No. 5,285,474, to Chow et al. have been developed. However, the reduction in computational complexity is achieved at an unacceptable cost of significant performance degradation or convergence instability in most real world applications.

An alternative solution to the TEQ problem includes minimizing wall energy with a constant constraint on the power of the target impulse response which leads to a computationally demanding Singular Value Decomposition (SVD) based algorithm. Wall energy is defined as the residual impulse response energy outside of the region corresponding to the target impulse response. One manner explored for enabling such wall energy minimization includes utilizing a least square fit based approximation. Unfortunately, this solution has proven to result in unacceptable levels of performance degradation.

An alternative solution to the above problem includes a conventional Minimum Mean Square Error (MMSE) approach, where the target impulse response (TIR) coefficients are assumed to be part of the desired final, filtered signal vector (the search vector). However, the squared norm constraint assumed in this approach to avoid an all-zeros solution leads to numerically difficult computations, such as an eigenvector computation to obtain TEQ coefficients. It is especially hard to implement direct adaptive training of the equalizer coefficients under this constraint.

While theoretically it may be possible to achieve improved performance using a significantly longer TEQ filter, the computation needs, power and silicon area required to implement such a long TEQ filter arrangement is not likely cost effective and largely impractical. Further, in practical applications, adaptive computation of TEQ filter coefficients is a necessity. Still further, most digital signal processors (DSPs) in practical applications support only fixed point arithmetic. As a result, finding stable adaptive algorithms with fixed point arithmetic to compute long TEQ filters may not be practical. Therefore, there is a need in the art of digital communication systems for a practical method and system for effectively and efficiently shortening the channel impulse response hₖ to a filtered channel impulse response zₖ.

The present invention overcomes the problems noted above, and provides additional advantages, by providing for a method of applying linear filtering to the received data set. The filtering is achieved by factoring the transmit data (xₖ) along a channel (hₖ) combined with additive disturbance/noise consideration (vₖ) to arrive at a combined unfiltered signal (yₖ), and in consideration of a hypothetical sampling of the transmit data along a delay channel (d) to arrive at a target impulse response. From this, the present invention derives a Minimum Mean Square Linearly Constrained Time Delay Equalization (MLC-TEQ) mathematical model and applies the target impulse response to achieve a shortened channel impulse response (zₖ). The shortened channel impulse response defined by processing the unfiltered received data (yₖ) through the TEQ coefficients and TEQ vector w^{T} is effectively compared with the hypothetical target channel impulse response (tₙ), which is derived from the delay channel as applied to (bₖ), to determine an error eₖ which is to be minimized by design. In this manner, the received data signal (yₖ) is converted into a TEQ filtered signal (zₖ) designed to approximate a desired target channel (tₙ). The invention shortens the overall channel response in a communication system such that the residual energy of the overall channel outside the target length is minimized. In addition, Inter Symbol Interference is minimized by the present invention.

The block diagram of FIG. 10c illustrates the inventive MLC-TEQ filter approach that overcomes the shortcomings of earlier approaches and yields the aforementioned advantages. In particular, a transmit data signal, xₖ 1000 is propagated along a channel 1012 having distortive effects on the signal, as represented by the h channel block 1012, and has an effective channel impulse response represented as hₖ at 1020. To more fully represent the effects of various processes on the transmit signal, a disturbance vector vₖ, which models the various receiver noises and interferences, at 1022 is applied to the channel impulse response to yield an unfiltered received data signal yₖ at 1024 that is received at an input of the TEQ filter 1014. By way of example, the received data signal yₖ could represent the input of a modem commonly used in communication systems. Unfiltered signal yₖ is the resultant vector of the current and previous N_{w} received samples, where N_{w} is defined as an integer representing the number of replicate received samples of transmitted data and represents TEQ length.

The unfiltered yₖ signal is passed through Time Domain Equalization (TEQ) filter 1014, which shortens the channel impulse response and generates a shortened channel impulse response signal zₖ at 1026. As shown by the hatched lines, a hypothetical parallel branch of the transmitted data signal is shown as a delay function (d) 1032 applied to a determined target vector bₖ to yield a target channel tₙ for modeling the shortened channel impulse response to arrive at the TEQ filter coefficients. In effect, the TEQ filter 1014 shortens the channel impulse response to minimize the mean square error eₖ, E(eₖ²), between the received signal and the hypothetical delay channel, thereby approximating the desired target channel.

As shown in FIG. 10c, hypothetically, the delay channel 1032 generates a signal at 1034 having a Target Impulse Response b 1036. The delay channel 1032 output is acted on by TIR b vector 1036 to produce the target impulse response channel tₙ is, in a sense, compared with the TEQ filter output vector zₖ 1026 resulting in a data error signal eₖ at 1004, which represents the kth error signal (that is, the error signal that corresponds to the resultant data signal). In determining the desired TEQ filter coefficients, eₖ is minimized.

In order to minimize the minimum mean least square error between the parallel communication channels (i.e., the impulse channel and the delay channel), it is necessary to calculate the TEQ filter coefficients used in generating the Equalizer Coefficient Vector w^{T} such that the resultant vector has minimum energy Inter Symbol Interference (ISI) and Inter Channel Interference (ICI).

The MLC-TEQ approach of the present invention provides a family of solutions that are parameterized by variables d ε{0, . . . , N_{C}+N_{TEQ}−N_{T}−2} and L ε{0, . . . , N_{T}−1}. It is further assumed that the channel impulse response {hᵢ, i ε{0, . . . , N_{C}−1}} and the noise autocorrelation sequence {rᵥ(i), i ε Z} are known or estimated. Each solution has a closed form expression in terms of d, L, {hᵢ, i ε{0, . . . , N_{C}−1}}, {rᵥ(i), i εZ}, TEQ length N_{TEQ} and the target impulse response length N_{T}. For fixed values of d and L, the MLC-TEQ filter determination steps are discussed in more detail below.

The approach embraced by the TEQ filter determination process of the present invention poses the TEQ problem as one of minimizing the error differentiating the parallel branches of the h channel 1012 and hypothetical d channel 1032 of FIG. 10c to determine the desired TEQ coefficients {wₖ}, represented as:

{wₖ;kε{1 . . . N_{TEQ}}}

and Target Impulse Response coefficients {bₖ} as:

{bₖ; kε{1, . . . ,N_{T}}}.

An additional constraint on w or b is used to avoid the trivial all zeros solution. In the present invention, that constraint is preferably on b, where one of the taps of b is constrained to be equal to a non-zero constant as b_{L}=c, where Lε{1 . . . N_{T}}, cε [symbol] , and c ≠0. C may be chosen as c=1 without a loss of generality. This constraint allows the use of linear mean square minimization techniques, and the resulting algorithm is therefore more suitable for fast and efficient direct adaptive implementations.

Due to the disturbance vₖ and the finite length constraint on b and w, the error sequence {eₖ} has been found to generally not be equal to zero. Therefore, the error may be minimized in order to create effective filtering. In one manner, the mathematical method of the present invention, targets the minimization of the mean square of error eₖ. In order to do so, the TEQ problem is preferably posed as to minimize E(eₖ²) for w and b such that b_{L}=1, where:

$$w = {[ {w}_{0} … {w}_{{N}_{T} - 1} ]}^{T} ; b = {[ {b}_{0} … {b}_{{N}^{P - 1}} ]}^{T} ;$$

and

E(eₖ²)

is the expected value (mean) of the square error, which is the minimization of mean square error by choosing vector variables w and b under the constraint that the Lth tap of vector b is constrained to be equal to 1. Minimization of E over w and the unconstrained components of b is a linear mean square minimization problem and the result for TEQ coefficient vector w is given as:

w^{T}=\overline{h}(Rᵥ/σₓ²+H(I−F^{T}F)H^{T})⁻¹

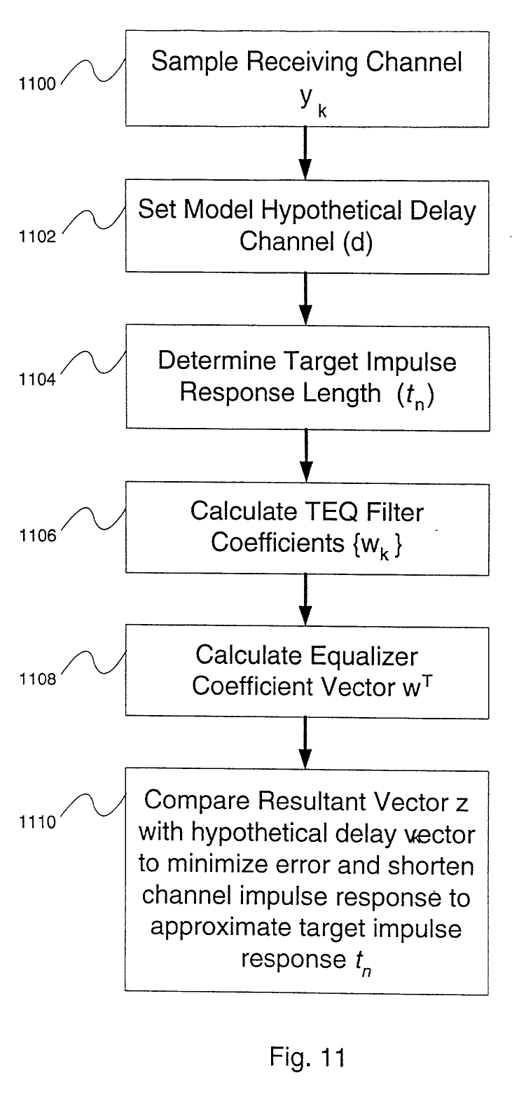

Referring now to the flow chart of FIG. 11, one embodiment of a method for determining a set of TEQ coefficients to be used to generate a signal vector zₖ in accordance with the present invention. Initially, in step 1100, the combination of the output of the h channel and the disturbance vector, yₖ, is sampled. In step 1102, the hypothetical delay channel d is set. The impulse response length of the target channel (tₙ) is determined in step 1104. Optimal TEQ filter coefficients {wₖ} are determined in step 1106, such that the number of bits of data loaded per symbol (B) is maximized while the channel impulse response is minimized to provide an output with minimal noise and heightened data density. In step 1108, an equalizer coefficient vector w^{T} is calculated based upon the TEQ filter coefficients defined in step 1106. In effect, the response zₖ is compared, as in step 1110, with the target impulse response channel (tₙ) vector b to generate optimal TEQ filter coefficients that result in minimizing the error of eₖ. By minimizing the error between the channels, the inventive method arrives at a set of coefficients wₖ and vector w^{T} to yield a shortened channel impulse response zₖ that approximates the target channel impulse response. In a one embodiment, the zₖ vector preferably has a length N_{T} and is the target impulse response vector.

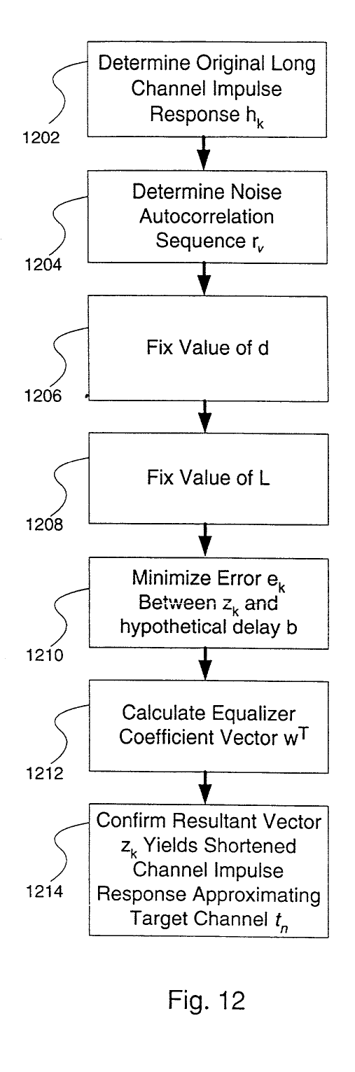

Referring now to the flow chart of FIG. 12, one embodiment of the operation of step 1106 is described. In step 1202 the original long channel impulse response hₖ is determined. In step 1204, the noise autocorrelation sequence, rᵥ, is determined. In step 1206, the delay value, d, is fixed as the starting location of the non-zero segment of the target impulse response. Similarly, a value for L is chosen and fixed as the center of the range of possible values that L can take, where L is calculated as:

$$L = ⌈ \frac{{N}_{P}}{2} ⌉$$

in step 1208, where L is an integer value used to set the target value of the length of the desired signal N_{T}. With hₖ, rᵥ, d and L known or fixed at certain values, the error between the parallel branches zₖ and bₖ may be minimized in step 1210.

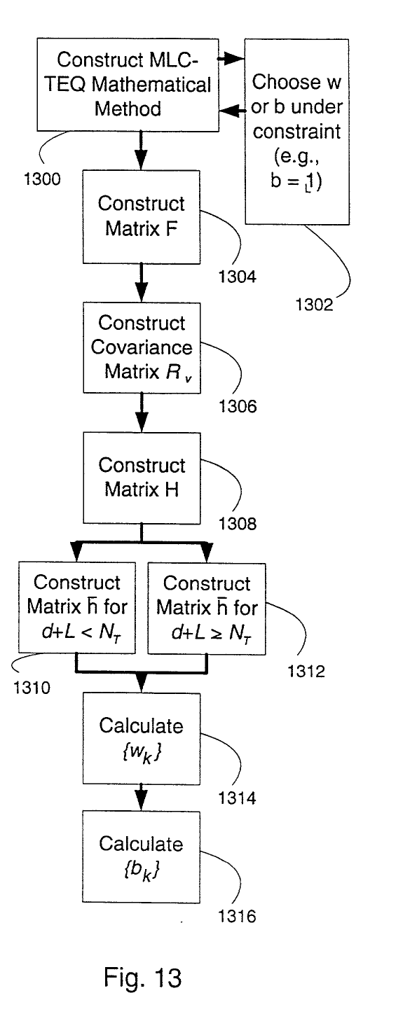

The specifics of step 1210 are discussed in more detail with reference to FIG. 13. In particular, FIG. 13 details an embodiment of a process used to calculate the TEQ filter {wₖ} and TIR filter {bₖ} coefficients. In order to minimize the error between zₖ and bₖ, a MLC-TEQ mathematical method is constructed in step 1300. In order to avoid the trivial all-zeros solution, a finite length constraint is imposed on b or w in step 1302. In the example of step 1302, one of the received signal channels, or “taps”, of b is constrained as b_{L}=c, where L ε{0, . . . ,N_{T}−1} and cε [symbol] , and c≠0. In this example, c is chosen to be c=1; this is done without a loss of generality.

A matrix F is constructed in step 1304 as:

$$F = [ \begin{matrix}{O}_{L , d} & {I}_{L , L} & {O}_{L , 1} & {O}_{L , NT - L - 1} & {O}_{L , NC + NTEQ - NT - d - 1} \\ {O}_{NT - L - 1 , d} & {O}_{NT - L - 1 , L} & {O}_{NT - L - 1 , 1} & {I}_{NT - L - 1 , NT - L - 1 ,} & {O}_{NT - L - 1 , NC + NTEQ - NT - d - 1}\end{matrix} ] .$$

A covariance matrix, Rᵥ, is constructed in step 1306 as:

$${R}_{vNTEQ , NTEQ} = [ \begin{matrix}{r}_{v} ( 0 ) & {r}_{v} ( 1 ) & ⋯ & {r}_{v} ( {N}_{TEQ} - 1 ) \\ {r}_{v} ( 1 ) & {r}_{v} ( 0 ) & ⋰ & {r}_{v} ( {N}_{TEQ} - 2 ) \\ ⋰ & ⋰ & ⋰ & ⋰ \\ {r}_{v} ( {N}_{TEQ} - 1 ) & {r}_{v} ( {N}_{TEQ} - 2 ) & ⋯ & {r}_{v} ( 0 )\end{matrix} ] .$$

A matrix H is constructed in step 1308 as:

$$H = [ \begin{matrix}{h}_{0} & {h}_{1} & ⋯ & ⋯ & ⋯ & {h}_{{N}_{C} - 1} & 0 & ⋯ & 0 \\ 0 & {h}_{0} & ⋯ & ⋯ & ⋯ & {h}_{{N}_{C} - 2} & {h}_{{N}_{C} - 1} & ⋯ & 0 \\ ⋰ & ⋰ & ⋰ & ⋰ & ⋰ & ⋰ & ⋰ & ⋰ & \\ ⋯ & ⋯ & 0 & {h}_{0} & ⋯ & ⋰ & ⋯ & ⋯ & {h}_{{N}_{C} - 1}\end{matrix} ] .$$

Further, in step 1310, a matrix \overline{h} is constructed for d+L<N_{TEQ} as:

\overline{h}=[h_{d+L} . . . h₀ 0_{1,N}_{_{TEQ}}_{-d-L-1}]

and for d+L≧N_{TEQ} in step 1312 as:

\overline{h}=[h_{d+L} . . . h_{d+L-N}_{_{TEQ}}₋₁]

The N_{TEQ} FIR TEQ coefficients {wₖ} are calculated in step 1314, as are the target impulse response coefficients {bₖ} in step 1316.

Returning now to FIG. 12, once the above values have been calculated, the various F, Rᵥ, H and \overline{h} and the coefficients {wₖ} are then used to calculate the Equalizer Coefficient vector w^{T} in step 410 as:

w^{T}=\overline{h}(Rᵥ/σₓ²+H(I−F^{T}F)H^{T})⁻¹

where: \overline{h} is a function of the impulse response coefficient; R_{V NTEQ,NTEQ} is a noise autocorrelation function; σₓ² is the variance of xₖ; H is a function of the channel impulse response; I is a function of the energy of the ISI and ICI interferences; F is an intermediate variable; and

wΔ[w₀ . . . w_{N}_{_{TEQ}}₋₁]^{T}

or the change from w₀^{T} to w_{NTEQ-1}^{T}.

It should be understood that the choices of the parameters d and L has a certain impact upon the performance of the TEQ filter with respect to a chosen application. Relating specifically to a DMT application, a reasonable capacity performance is obtained by choosing d as the location of the maximum value of the impulse response {hₙ}.

Further, it has been observed that for a typical scenario, there is a relatively wide region around d_{c} where the performance of the filter does not change, where d_{c} is the effective delay corresponding to the starting location of the non-zero segment of the impulse response. For the L parameter, a reasonable choice is given by the equation:

$$L = ⌈ \frac{{N}_{T}}{2} ⌉$$

where ┌x┐ is a function representing the smallest integer that is greater than or equal to the number x. Therefore, L is chosen as the center of the range of possible values that L can take.

From the detailed description above, it will be clear to one skilled in the art that the present invention has many benefits. In particular, the fundamental advantages are two fold: it provides linear TEQ filtering with near-optimal performance, and it is structurally suitable for adaptive implementation on a real system. In particular, and in contrast to the filtering methods currently used in the art, this method includes: the Target Impulse Response (TIR) vector is the combined response of the transmission channel and the TEQ filter is used as the search vector; the MLC-TEQ mathematical method constrains one element of the TIR vector to be equal to a constant and the element can be any element of the TIR vector; the error is computed using the difference between the TEQ output and the TIR filter output; the TEQ filter coefficients are computed by minimizing the Mean Square Error (MSE) criterion; and the mathematical method provides a family of TEQ vectors which are parametized by two quantities, the location of the constrained element of the TIR vector and the delay value used in the computation.

In its Hadrian™ and Antoninus™ products, Virata Corporation of Santa Clara, Calif., extends the benefits of an integrated full-rate ADSL CPE chipset. The inventive concepts discussed above may be incorporated into an integrated ADSL CPE processor and Analog Front End/Line Driver (AFE/LD) chipset, such as Virata Corporation's Hadrian™ and Antoninus™, which may be used in a wide variety of applications. According to one embodiment of the present invention, the inventive concepts related to echo cancellation functionality and TEQ functionality may be incorporated into the Hadrian and/or Antoninus products.

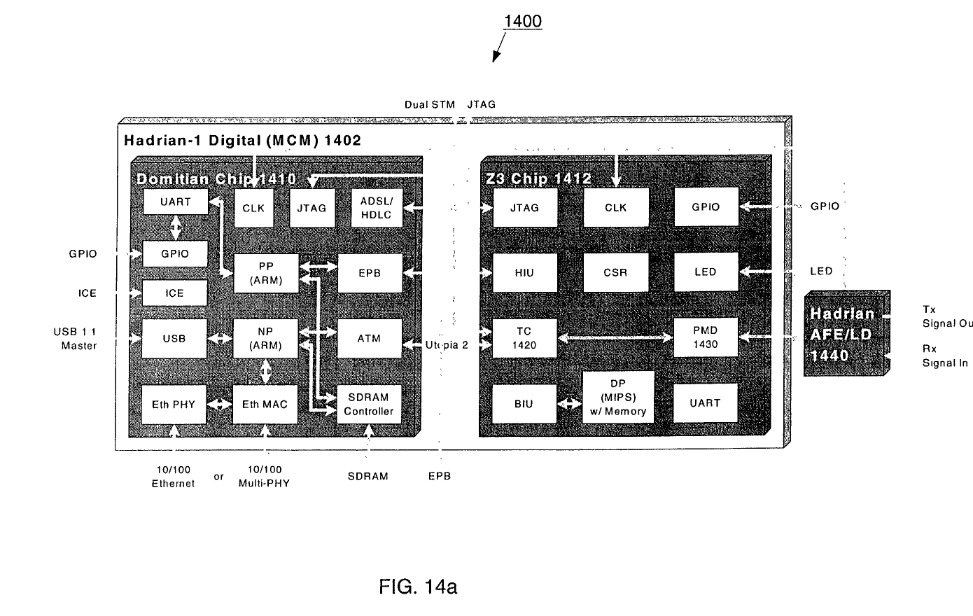

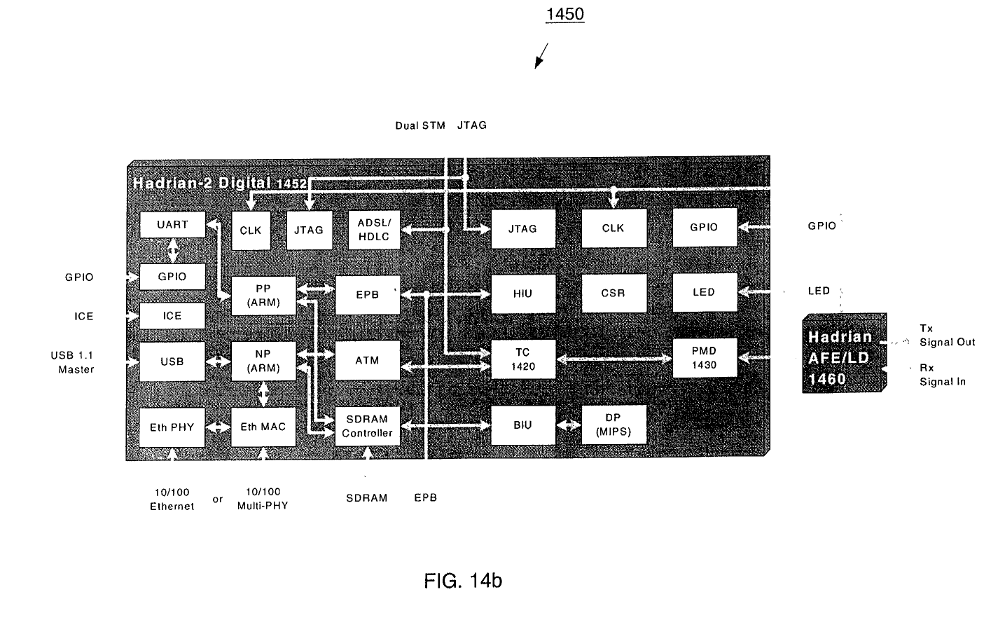

FIGS. 14a and 14b are schematic diagrams of hardware architectures in which the inventive aspects of the present invention may be incorporated. FIG. 14a illustrates a block diagram of a chip architecture 1400 for Hadrian 1, which includes an integrated ADSL CPE processor 1402 and AFE/LD chipset 1440. The integrated ADSL CPE processor 1402 may be delivered as a multi-chip module (MCM) including Z3 chip 1412 and Domitian Chip 1410. Z3 chip 1412 is full-rate ADSL Physical Layer (PHY) for CPE with on-chip DP (e.g., DSL PHY Processor) code storage memory. Domitian chip 1410 is a high performance communications processor for CPE with Ethernet PHY. Hadrian AFE/LD 1440 is an AFE with integrated line driver for full-rate ADSL CPE, as a part of the chip-set. The Hadrian AFE/LD 1440 is an integral part of the complete solution. The Hadrian Integrated ADSL CPE Processor 1402 is compatible with the Hadrian AFE/LD 1440.

The Hadrian-1 chipset, as shown in FIG. 14a, is designed to be fully compliant with the full-rate ADSL ITU standard G.992.1 (G.dmt) and the splitterless ADSL ITU standard G.992.2 (G.lite). Hadrian-1 fully supports Annex A, both Frequency Division Duplex (FDD) and Echo Cancelled (EC) modes, and Annex B of G.992.1 and Annex A and B of G.992.2. In addition, the initialization procedure is fully compliant with G.994.1 (Rev. 2) (G.hs.bis). Other features may include being fully compliant with the splitterless ADSL ITU standard G.992.2 (G.lite) and supporting both Annex A and B. Hadrian 1 may also include a communications processor with Protocol Processor (PP) for protocol execution and Network Processor (NP) for data manipulation. Other features may include DSL PHY Processor (DP) for implementing modem firmware; Internal 10/100 Ethernet PHY (disabled when Media Independent Interface (MII) interface is used); 10/100 Ethernet MAC with MII for connecting to either internal 10/100 Ethernet PHY or external 10/100 multi-PHY; External Peripheral Bus (EPB); Synchronous Transfer Mode (STM): Serial frame data (e.g., High-Level Data Link Control (HDLC)); simultaneous STM and ATM support; bearer channels AS0, AS1, LS0, LS1 for both STM and ATM; single and dual latency paths for both downstream and upstream; four framing modes, e.g., modes 0, 1, 2, and 3; Network Timing Reference (NTR) transport support; dying gasp detection and handling; Universal Serial Bus (USB) 1.1 slave; integrated line driver and Voltage Controlled Crystal Oscillator (VCXO) for the AFE; general purpose input/output (GPIO); universal asynchronous receiver/transmitter (UART); In-Circuit Emulator (ICE); and/or Joint Test Action Group (JTAG).

In particular, standard compliance includes the power spectral density (PSD) of the transmit signals for all supported annex and corresponding modes; the use of frequency bins for transmit and receive signal including pilot bins; handshake procedure as specified in G.994.1; various initialization, training, and message signals; state machine and timing sequence; DMT modulation; framing modes; bearer channels and dual latency paths; Embedded Overhead Control (EOC) channel; ADSL Overhead Control (AOC) Channel; forward error correction; inter-leaver operation; and ATM and STM functionalities. Hadrian-1 is interoperable with standard compliant central office (CO) equipment, including various DSL Access Multiplexor (DSLAM) vendors.

FIG. 14b illustrates Hadrian 2, which includes an integrated ADSL CPE Processor 1452 and AFE/LD 1460 chipset, as shown by 1450. Hadrian 2 ADSL CPE processor 1452 may be delivered as a single-chip and cost-optimized device, which includes Z3 chip and Domitian chip. Z3 chip is a full-rate ADSL PHY for CPE without on-chip DP code storage memory. Domitian chip is a communications processor for CPE with Ethernet PHY and with SDRAM interface capable of handling various processors, such as Network Processor (NP), Protocol Processor (PP) and DSL PHY Processor (DP). Hadrian AFE/LD 1460 is an AFE with integrated line driver for full-rate ADSL PHY for CPE and will also be included as part of a chip-set. Hadrian 2 may support the above listed features for Hadrian 1 in addition to STM: TDM H.110, ST-Bus.

The Domitian communications processor has been architected around the principle that there are two functions of a communications system which may use different architectures. These two functions are data manipulation and protocol execution.

Data manipulation involves many word, byte and bit changes on small amounts of data. These operations have a deterministic character and are finished in a short time span. The code controlling these operations are small and compact, often written in assembly language, and involves a detailed knowledge of low level data protocols (Open Source Initiative (OSI) layer 1 to layer 3) and the available hardware. Data is processed in cells and packets of limited size.

The protocol stack routines are multitasking, involving a large amount of memory and although time limits are set, these are not as strict as for the low level data manipulation routines. The data consists of frames which can be large (e.g., up to 64K).

The Domitian architecture reflects these two types of function. The Protocol Processor (PP) has a 4 KB cache and is thus suited for running large programs. It has no direct access to the network data port but can exchange data with the Network Processor (NP) using shared Synchronous Dynamic Random-Access Memory (SDRAM). Large frames of data may be easily exchanged between the two processors using this method. The main PP tasks are to set up and close connections, get data from the NP, convert the data from one protocol type to another and pass them back to the NP again to be transferred to another network interface. For protocol support, it may also generate its own data frames for signalling, operating and maintenance. The PP may also communicate with, and control external hardware using the External Peripheral Bus (EPB).

The Network Processor (NP) has a dedicated local program memory (e.g., 16 KB of SRAM) and may directly interact with network ports and associated hardware. A main tasks involves assembling incoming packets into frames for each of the network connections. It knows the status of each network port and responds to any incoming packet/cell in time to prevent buffer overflow. While receiving packets/cells, it assembles them into frames, keeps track of errors, gathers statistical data, performs policing, extraction of Operation, Administration and Maintenance (OAM) cells, etc. When transmitting data, it segments frames into packets/cells, transmits at a specified rate by inserting idle cells, adds Cyclic Redundancy Check (CRC) bytes, inserts OAM cells, etc.

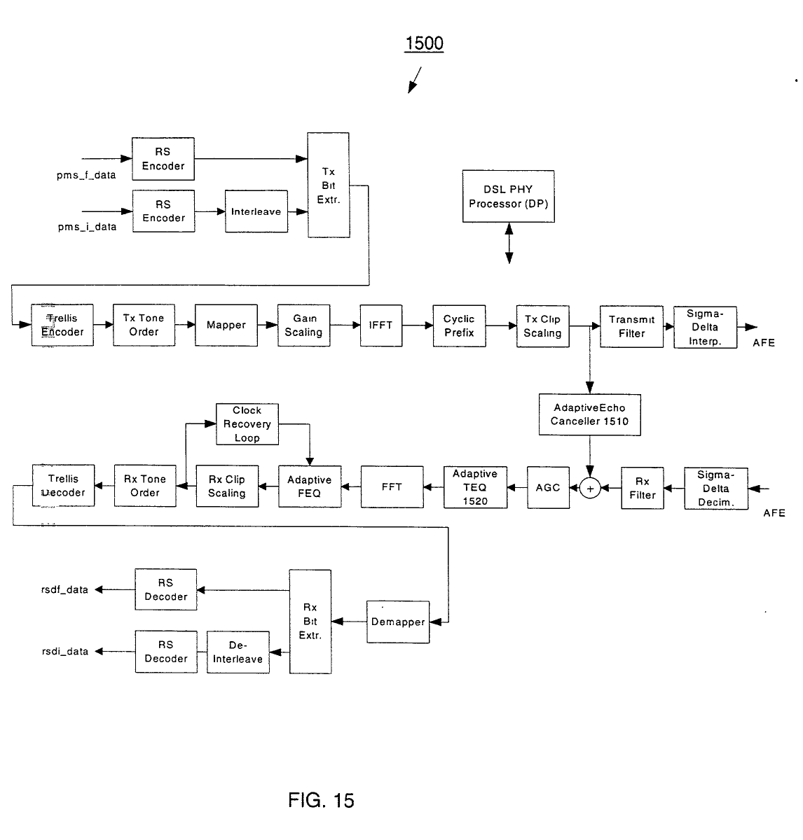

FIG. 15 is a block diagram of a physical media dependent (PMD) layer 1500 of a ADSL CPE chip in which the inventive aspects of the present invention may be incorporated. FIG. 15 illustrates core building blocks for the PMD layer and basic signal flow. As shown in FIGS. 14a and 14b, PMD 1430 is implemented in ADSL CPE Processor 1402 and 1452.

PMD layer may include a variety of functions, which may include a DSL PHY Processor (DP) for implementing modem firmware; a complete DMT engine including IFFT (e.g., 64-point, 128-point or multiples thereof) on the transmit path and a point Fast Fourier Transform (FFT) (e.g., 512-point) on the receive path, Tx/Rx Bit Extract, Cyclic Prefix, and Constellation encoder/decoder; a Forward Error Correction (FEC) mechanism including the mandatory Reed Solomon (RS) encoder/decoder and optional Trellis encoder/decoder; both fast and interleaved paths are supported along with the Interleaver/deinterleaver; Training Signals Generator and Sync Symbol Generator; Course/Fine Gain Scaling and Tx/Rx Clip Scaling; Programmable Transmit Filter and Receive Noise Reduction Filter; Digital Automatic Gain Control (AGC); Adaptive Time domain Equalization (TEQ); Adaptive Frequency domain Equalization (FEQ); Tone ordering and Bit Swap; Clock Recovery Loop (CRL); Sigma-Delta Interpolator and Decimator for Digital to Analog Converter (DAC) and Analog to Digital Converter (ADC); and Adaptive Echo Cancellation Filter.

As shown in FIG. 15, adaptive echo canceller 1510 may embody the inventive aspects related to echo cancellation of the present invention discussed above. In addition, adaptive TEQ 1520 may embody the inventive aspects of the TEQ of the present invention discussed above.

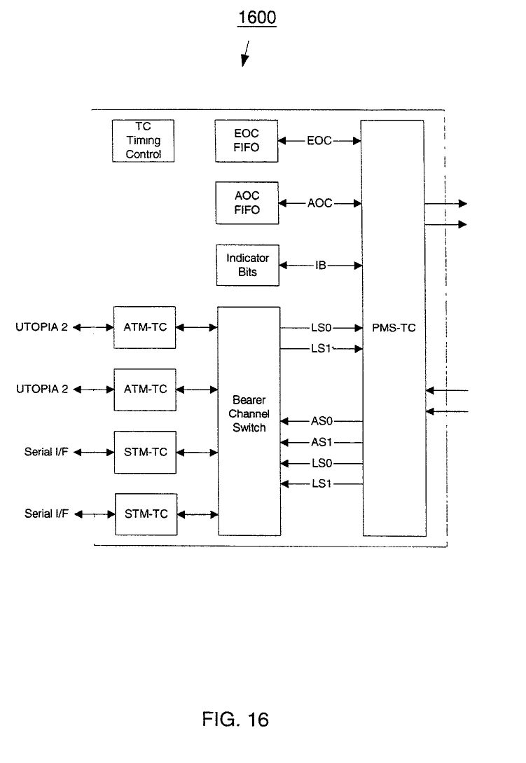

FIG. 16 is a block diagram of a transmission convergence (TC) layer 1600 of a ADSL CPE chip in which the inventive aspects of the present invention may be incorporated. As shown in FIGS. 14a and 14b, TC 1420 is implemented in ADSL CPE Processor 1402 and 1452. The TC layer may support a variety of features, such as ATM-TC; STM-TC; dual-bearer; simultaneous ATM and STM transport; Bearer Channel Switch; UTOPIA 2 interface; ADSL Overhead Control/Embedded Overhead Control (AOC/EOC) Buffers; Tx/Rx CRC; and Scrambler/Descrambler.

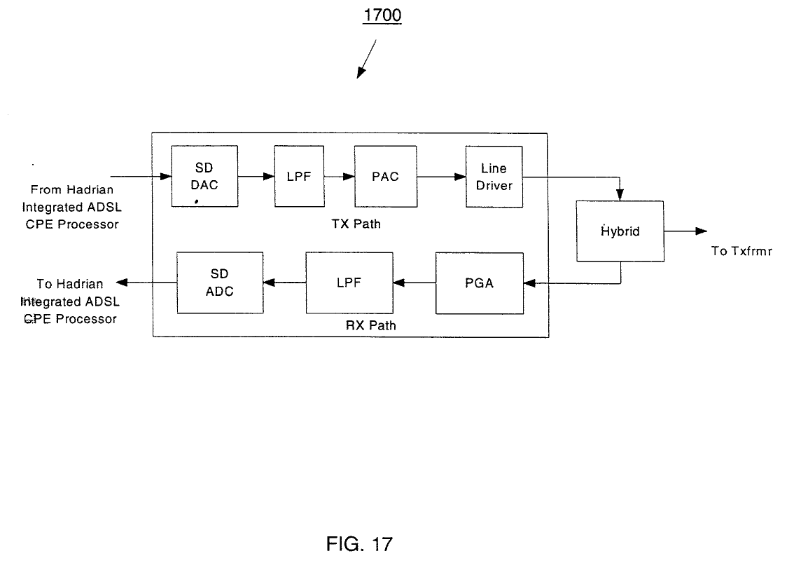

FIG. 17 is a block diagram of an analog front end device in which the inventive aspects of the present invention may be incorporated. Hadrian AFE/LD, as shown by 1440 and 1460 in FIGS. 14a and 14b, with integrated line driver is an integral part of the complete solution. To achieve enhanced performance the Hadrian AFE/LD and its Hadrian Integrated ADSL CPE Processor counterpart are designed with tightly coupled architecture. AFE features may include an integrated line driver; an integrated VCXO; 16-bit DAC with 14.5 effective bits; 16-bit ADC with 13.5 effective bits; industrial temperature range: −40C—85C; and external filters.

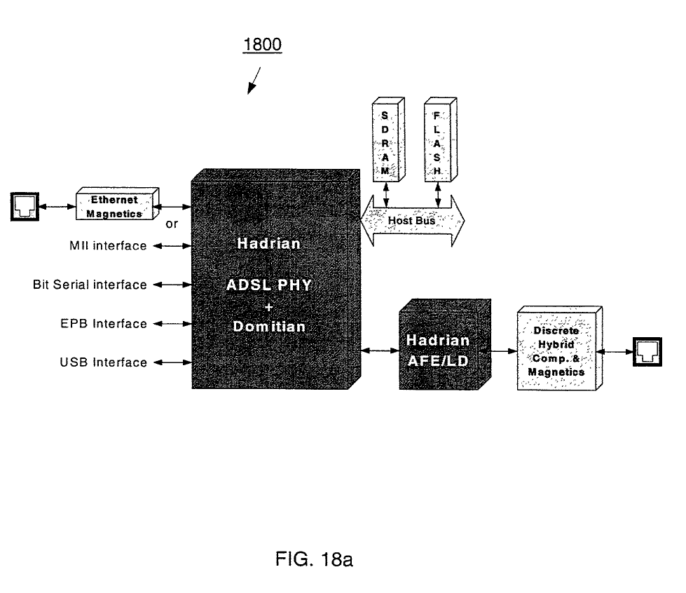

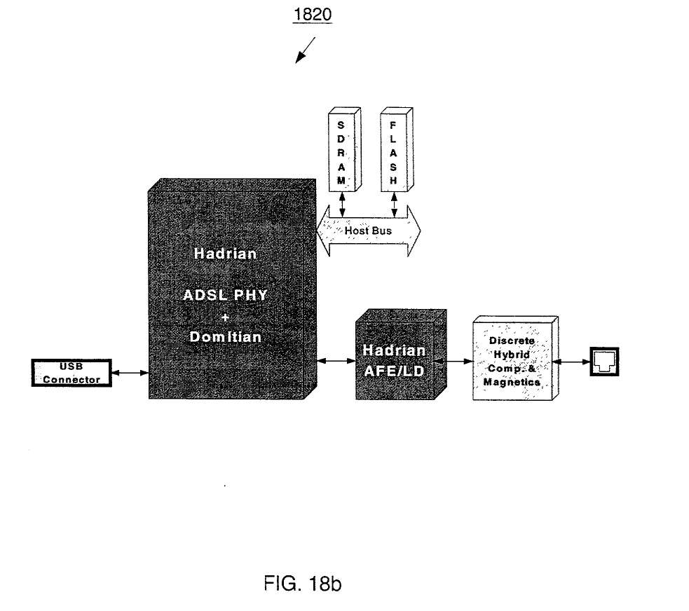

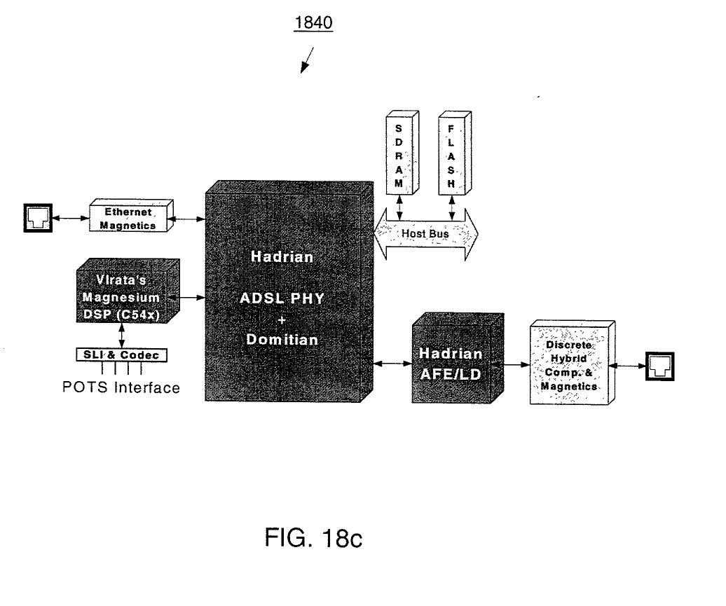

FIGS. 18a-18c are a block diagram of applications in which the inventive aspects of the present invention may be incorporated. FIG. 18a illustrates an Ethernet Router/Bridge 1800 which incorporates the Hadrian product. FIG. 18b illustrates a USB Modem and USB-Attached Gateway 1820 which incorporates the Hadrian product. FIG. 18c illustrates an Integrated Access Device (IAD) 1840 which incorporates the Hadrian product.

Virata's Antoninus is a full-rate ADSL CPE PHY device comprised of two chips, which includes an ADSL CPE Processor called Z3 (as discussed above in connection with Hadrian 1) and a AFE/LD chipset, as illustrated in FIG. 17. The Z3 chip is a full-rate ADSL PHY for CPE with on-chip DP (e.g., DSL PHY processor) code storage memory. The ADSL CPE processor Z3 is also used in Hadrian 1, discussed above. Similarly, the inventive aspects related to the echo canceller and the TEQ may be implemented in the Antoninun product. Antoninus AFE/LD is an AFE with integrated line driver for full-rate ADSL CPE, which is also included as part of the chip-set.

While the foregoing description includes many details and specificities, it is to be understood that these have been included for purposes of explanation only, and are not to be interpreted as limitations of the present invention. Many modifications to the embodiments described above can be made without departing from the spirit and scope of the invention.

The present invention is not to be limited in scope by the specific embodiments described herein. Indeed, various modifications of the present invention, in addition to those described herein, will be apparent to those of ordinary skill in the art from the foregoing description and accompanying drawings. Thus, such modifications are intended to fall within the scope of the following appended claims. Further, although the present invention has been described herein in the context of a particular implementation in a particular environment for a particular purpose, those of ordinary skill in the art will recognize that its usefulness is not limited thereto and that the present invention can be beneficially implemented in any number of environments for any number of purposes. Accordingly, the claims set forth below should be construed in view of the full breath and spirit of the present invention as disclosed herein.

1. A method for determining a finite impulse response time domain equalization filter for shortening a channel impulse response in an asymmetric, dual rate data transmission system, the transmission system characterized by a transmitted signal xₖ having an original channel impulse response hₖ, which effectively combines with a disturbance vector vₖ to result in a TEQ filter inpur signal, yₖ, the method comprising the steps of:
sampling yₖ;
applying a delay channel (d), which is based at least in part on transmitted signal xₖ, with a target channel vector b, which is constrained so as to avoid an all-zeros solution; and
calculating a vector w^{T} so as to minimize the error, eₖ, between a shortened channel impulse response, zₖ, and the target channel impulse response.

2. The method of claim 1, wherein yₖ has an overall effective length N_{C} and an effective delay channel (d).

3. The method of claim 2, wherein the effective delay channel d corresponds to the starting location of the non-zero segment of the channel impulse response.

4. The method of claim 1, wherein zₖ has a channel length of N_{TEQ} that is modeled to match desired target channel length N_{T} of the target channel impulse response.

5. The method of claim 1, wherein hₖ comprises one or more replicates of a received data set {xₖ;kεZ}.

6. The method of claim 1, wherein xₖ is a received signal in a communications system.

7. The method of claim 6, wherein the said communications system is a Discrete Multitone (DMT) communications system.

8. The method of claim 1, further comprising the step of modeling wₖ such that the number of bits loaded per symbol, B, is maximized.

9. The method of claim 1, wherein the vector w^{T} is calculated using filter coefficients {wₖ;kε{1 . . . N_{TEQ}}} as:
w^{T}=\overline{h}(Rᵥ/σₓ²+H(I−F^{T}F)H^{T})⁻¹.
where:
\overline{h} is a function of the impulse response coefficient;
R_{V} is a noise autocorrelation function;
σₓ² is the variance of xₖ;
H is a function of the channel impulse response;
I is a function of the energy of the Inter-Symbol Interference (ISI) and the Inter-Channel Interference (ICI);
F is an intermediate variable; and
wΔ[w₁ . . . w_{N}_{_{TEQ}}]^{T}.

10. The method of claim 9, wherein the filter coefficients wₖ are TEQ filter length (N_{TEQ}).

11. The method of claim 10, wherein N_{TEQ} is predetermined.

12. The method of claim 9, further comprising the step of calculating F as:
$$F = [ \begin{matrix}{O}_{L , d} & {I}_{L , L} & {O}_{L , 1} & {O}_{L , NT - L - 1} & {O}_{L , NC + NTEQ - NT - d - 1} \\ {O}_{NT - L - 1 , d} & {O}_{NT - L - 1 , L} & {O}_{NT - L - 1 , 1} & {I}_{NT - L - 1 , NT - L - 1 ,} & {O}_{NT - L - 1 , NC + NTEQ - NT - d - 1}\end{matrix} ]$$

13. The method of claim 9, further comprising the step of calculating Rv as:
$${R}_{vNTEQ , NTEQ} = [ \begin{matrix}{r}_{v} ( 0 ) & {r}_{v} ( 1 ) & ⋯ & {r}_{v} ( {N}_{TEQ} - 1 ) \\ {r}_{v} ( 1 ) & {r}_{v} ( 0 ) & ⋰ & {r}_{v} ( {N}_{TEQ} - 2 ) \\ ⋰ & ⋰ & ⋰ & ⋰ \\ {r}_{v} ( {N}_{TEQ} - 1 ) & {r}_{v} ( {N}_{TEQ} - 2 ) & ⋯ & {r}_{v} ( 0 )\end{matrix} ]$$

14. The method of claim 9, further comprising the step of calculating H as:
$$H = [ \begin{matrix}{h}_{0} & {h}_{1} & ⋯ & ⋯ & ⋯ & {h}_{{N}_{C} - 1} & 0 & ⋯ & 0 \\ 0 & {h}_{0} & ⋯ & ⋯ & ⋯ & {h}_{{N}_{C} - 2} & {h}_{{N}_{C} - 1} & ⋯ & 0 \\ ⋰ & ⋰ & ⋰ & ⋰ & ⋰ & ⋰ & ⋰ & ⋰ & \\ ⋯ & ⋯ & 0 & {h}_{0} & ⋯ & ⋰ & ⋯ & ⋯ & {h}_{{N}_{C} - 1}\end{matrix} ]$$

15. The method of claim 9, further comprising the step of calculating \overline{h} for d+L≧N_{TEQ} as:
\overline{h}=[h_{d+L} . . . h₀ 0_{1,N}_{_{TEQ}}_{-d-L-1}]

16. The method of claim 9, further comprising the step of calculating \overline{h} for d+L<N_{TEQ} as:
\overline{h}=[h_{d+L} . . . h_{d+L-N}_{_{TEQ}}₋₁]

17. The method of claim 1 wherein the filter coefficients wₖ are calculated using a Minimum Mean Square Error Linearly Constrained TEQ (MLC-TEQ) algorithm.

18. The method of claim 1 wherein the channel impulse response is converted into an impulse response that has effectively N_{P} nonzero entities.

19. The method of claim 18, further comprising the step of modeling said nonzero entities with the target impulse response coefficients sequence {bₖ; kε{0 . . . N_{P}−1}}.

20. The method of claim 19, further comprising the step of formulating the target channel, tₙ, as:
$${t}_{n} = \{ \begin{matrix}{b}_{n - d} & d \leq n \leq d + {N}_{P} - 1 \\ 0 & otherwise ,\end{matrix} \}$$
where d is the effective delay corresponding to the starting location of the non-zero segment of the impulse response.

21. The method of claim 1, further comprising the step of constraining any one element of the b vector to be equal to a constant.

22. The method of claim 1, further comprising the step of calculating an error eₖ.

23. The method of claim 22, wherein said error is calculated using the difference between the TEQ filter output and the TIR output.

24. The method of claim 23, further comprising the step of calculating the Mean Square of the Error (MSE), E(eₖ²).

25. The method of claim 24, wherein Mean Square Error (MSE) is minimized.

26. The method of claim 1, wherein the TEQ filter coefficients are computed by minimizing the Mean Square Error (MSE) criterion.

27. The method of claim 1, wherein the TEQ filter coefficients are parameterized by two quantities.

28. The method of claim 27, wherein the the two quantities are:
the location (L) of the constrained element of the TIR vector; and
the delay value (d) used in the computation.

29. The method of claim 28, wherein the location of the constrained element of the TIR vector, L, is:
Lε{0, . . . , N_{P}−1}.

30. The method of claim 28, wherein the said delay value, d, is:
dε{0, . . . , N_{C}+N_{T}−N_{P}−2}.

31. The method of claim 1, further comprising the step of modeling, by a linear time invariant system with the impulse response of the h channel, {hᵢ;iε{0, . . . , N_{C}−1}}, the combined effects of transmit filter shaping, receiver filter effects, and distortion effects caused by the transmission channel.

32. The method of claim 31, further comprising the step of choosing wₖ such that the number of bits loaded per symbol, B, is maximized.

33. The method of claim 32, wherein:
$$B ( w ) = {\sum }_{i {∈}^{T}} {log}_{2} \{ 1 + \frac{{S}_{i} ( w )}{( {I}_{i} ( w ) + {N}_{i} ( w ) ) Γ} \}$$
where T is the set of transmit tones,
Sᵢ(w) is the desired signal energy at tone i,
Iₗ(w) is the combined energy of ISI and ICI at tone i caused by the components of tₙ outside d≦n≦d+N_{P}−1,
Nᵢ(w) is the noise energy at tone I, and
Γ is the effective gap which is a function of the constellation, coding gain, and the margin requirement.

34. The method of claim 28, wherein the location of the constrained element of the TIR vector, L, is:
Lε{0, . . . , N_{P}−1}.

35. The method of claim 34, wherein:
$$L = ⌈ \frac{{N}_{P}}{2} ⌉$$

36. The method of claim 35, wherein L is chosen as the center of the range of possible values that L can take.

37. The method of claim 36, further comprising the step calculating TEQ coefficients {wₖ} and target impulse response coefficients {bₖ; kε{0, . . . , N_{P}−1}}.

38. The method of claim 36, further comprising the step of imposing a constraint, b_{L}=c, on b, where:
Lε{0 . . . N_{P}−1},
cε [symbol] , and
c≠0.

39. The method of claim 38, wherein c=1.

40. The method of claim 1, further comprising the step of minimizing an error sequence, {eₖ}, between h and d.

41. The method of claim 40, further comprising the step of minimizing the mean square of error {eₖ}.

42. The method of claim 1, wherein the target channel is designed to be:
$${t}_{n} = \{ \begin{matrix}{b}_{n - d} & d \leq n \leq d + {N}_{P} - 1 \\ 0 & otherwise ,\end{matrix} \}$$
where d is the effective delay corresponding to the starting location of the non-zero segment of the impulse response.

43. A data channel receiving device having a TEQ filter for filtering a data set {yₖ;kεZ}, the TEQ filter comprising:
means for sampling yₖ;
means for modeling a target channel impulse response, bₖ, based at least in part on applying a delay channel (d) with a target vector b; and
means for deriving TEQ coefficients {wₖ} by minimizing the error, eₖ, between a shortened channel impulse response, zₖ, and the target channel impulse response.

44. The device of claim 43, wherein the shortened channel impulse response, zₖ, is derived at least in part by calculating a vector w^{T}.

45. The device of claim 43, wherein the TEQ filter is part of a modem.

46. The device of claim 43, wherein the transmitted signal, xₖ, received by the TEQ filter through the channel h and distorted by the disturbance vector, vₖ, originates from a modem device.

47. The device of claim 43, wherein the target vector b is constrained to avoid an all-zeroes solution.
